(19) United States
(12) Patent Application Publication
(10) Pub. No.: US 2026/0123404 A1
(43) Pub. Date: Apr. 30, 2026

(54) PACKAGE STRUCTURE

(71) Applicant: Advanced Semiconductor Engineering, Inc., Kaohsiung (TW)

(72) Inventors: Cheng-Lan LIN, Kaohsiung (TW); Guo-Cheng LIAO, Kaohsiung (TW)

(73) Assignee: Advanced Semiconductor Engineering, Inc., Kaohsiung (TW)

(21) Appl. No.: 18/927,805

(22) Filed: Oct. 25, 2024

(51) Int. Cl. H01L 23/367; H01L 23/00; H01L 23/373; H01L 23/498; H01L 25/03

(52) U.S. Cl. CPC H10W 40/22; H10W 40/259; H10W 42/121; H10W 70/65; H10W 70/685; H10W 90/00; H10W 90/701; H10W 70/66

(57) ABSTRACT

A package structure includes a substrate, an electronic device and a heat dissipating structure. The electronic device is disposed over the substrate. The heat dissipating structure is disposed over the substrate and is attached to the electronic device. The heat dissipating structure includes a heat dissipating portion and a conductive portion. The heat dissipating portion is configured to guide a heat generated by the electronic device to an outside of the package structure. The conductive portion is electrically connected to the substrate, and extends through the heat dissipating portion

### BACKGROUND

### 1. Field of the Disclosure

The present disclosure relates to a package structure, and to a package structure including a heat dissipating structure.

### 2. Description of the Related Art

In a semiconductor package structure, especially a package on package (POP) structure, an electronic device is mounted to a top surface of a substrate of a bottom package. In addition, the bottom package further includes a molding compound that is formed or disposed on the top surface of the substrate so as to encapsulate the electronic device. The molding compound has a low thermal conductivity, and will adversely influence the heat dissipation efficiency of the semiconductor package structure during operation. Thus, the reliability, yield and lifetime of the semiconductor package structure may be low.

### SUMMARY

In some embodiments, a heat dissipating structure includes a porous structured main body and an electrical through via. The main body has a first surface and a second surface opposite to the first surface. The electrical through via is embedded in the porous structured main body, and extends from the second surface of the porous structured main body to the first surface of the porous structured main body. A hardness of the porous structured main body is greater than a hardness of the electrical through via. The electrical through via is an electrical connection element embedded in the porous structured main body of the heat dissipating structure. Thus, the heat dissipating structure has an electrical function. In another embodiment, one or more heat dissipating elements and one or more electrical connection element are spaced apart from each other. In another embodiment, a heat dissipating element includes a monolithic metal material, which cannot be used as an electrical connection element.

In some embodiments, a package structure includes a substrate, an electronic device and a heat dissipating structure. The electronic device is disposed over the substrate. The heat dissipating structure is disposed over the substrate and is attached to the electronic device. The heat dissipating structure includes a heat dissipating portion and a conductive portion. The heat dissipating portion is configured to guide a heat generated by the electronic device to an outside of the package structure. The conductive portion is electrically connected to the substrate, and extends through the heat dissipating portion.

In some embodiments, a package structure includes a circuit pattern structure, an electronic device, a reinforcement structure and a conductive bonding element. The electronic device is disposed over the circuit pattern structure. The reinforcement structure is spaced apart from the circuit pattern structure, and accommodates the electronic device. The reinforcement structure includes a main body and an electrical through via embedded in the main body. The conductive bonding element bonds the reinforcement structure and the circuit pattern structure. The main body of the reinforcement structure is configured to reduce a warpage of the circuit pattern structure 1 during a thermal process.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a package structure according to some embodiments of the present disclosure.

FIG. 2 illustrates an enlarged view of an area “A”of FIG. 1.

FIG. 2A illustrates a cross-sectional view taken along line I-I in FIG. 1.

FIG. 2B illustrates a cross-sectional view of a package structure according to some embodiments of the present disclosure.

FIG. 3 illustrates a cross-sectional view of a package structure according to some embodiments of the present disclosure.

FIG. 4 illustrates an enlarged view of an area “B”of FIG. 3.

FIG. 4A illustrates a cross-sectional view of a package structure according to some embodiments of the present disclosure.

FIG. 5 illustrates one or more stages of an example of a method for manufacturing a package structure according to some embodiments of the present disclosure.

FIG. 6 illustrates one or more stages of an example of a method for manufacturing a package structure according to some embodiments of the present disclosure.

FIG. 7 illustrates one or more stages of an example of a method for manufacturing a package structure according to some embodiments of the present disclosure.

FIG. 8 illustrates one or more stages of an example of a method for manufacturing a package structure according to some embodiments of the present disclosure.

FIG. 9 illustrates one or more stages of an example of a method for manufacturing a package structure according to some embodiments of the present disclosure.

FIG. 10 illustrates one or more stages of an example of a method for manufacturing a package structure according to some embodiments of the present disclosure.

FIG. 11 illustrates one or more stages of an example of a method for manufacturing a package structure according to some embodiments of the present disclosure.

FIG. 12 illustrates one or more stages of an example of a method for manufacturing a package structure according to some embodiments of the present disclosure.

FIG. 13 illustrates one or more stages of an example of a method for manufacturing a package structure according to some embodiments of the present disclosure.

FIG. 14 illustrates one or more stages of an example of a method for manufacturing a package structure according to some embodiments of the present disclosure.

FIG. 15 illustrates one or more stages of an example of a method for manufacturing a package structure according to some embodiments of the present disclosure.

FIG. 16 illustrates one or more stages of an example of a method for manufacturing a package structure according to some embodiments of the present disclosure.

FIG. 17 illustrates one or more stages of an example of a method for manufacturing a package structure according to some embodiments of the present disclosure.

FIG. 18 illustrates one or more stages of an example of a method for manufacturing a package structure according to some embodiments of the present disclosure.

FIG. 19 illustrates one or more stages of an example of a method for manufacturing a package structure according to some embodiments of the present disclosure.

FIG. 20 illustrates one or more stages of an example of a method for manufacturing a package structure according to some embodiments of the present disclosure.

FIG. 21 illustrates one or more stages of an example of a method for manufacturing a package structure according to some embodiments of the present disclosure.

FIG. 22 illustrates one or more stages of an example of a method for manufacturing a package structure according to some embodiments of the present disclosure.

FIG. 23 illustrates one or more stages of an example of a method for manufacturing a package structure according to some embodiments of the present disclosure.

FIG. 24 illustrates one or more stages of an example of a method for manufacturing a package structure according to some embodiments of the present disclosure.

FIG. 25 illustrates one or more stages of an example of a method for manufacturing a package structure according to some embodiments of the present disclosure.

FIG. 26 illustrates one or more stages of an example of a method for manufacturing a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

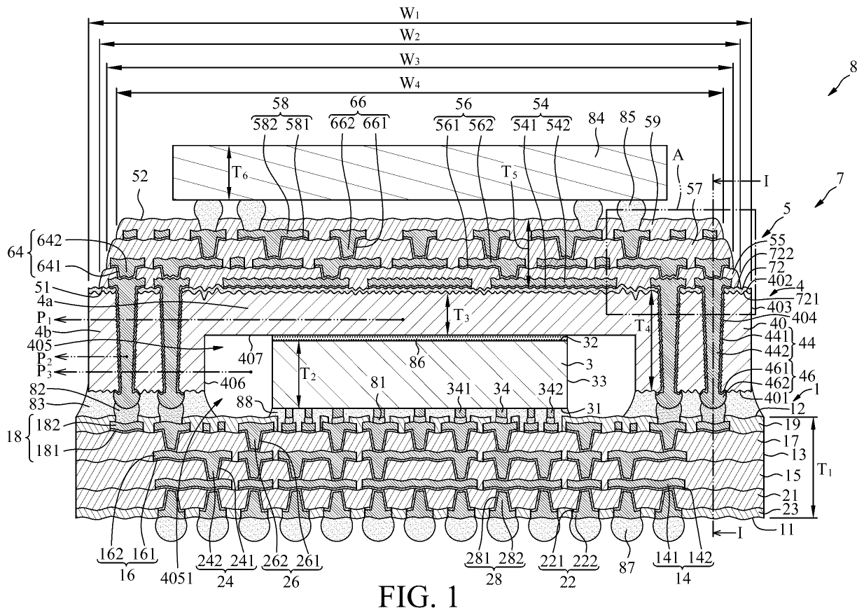

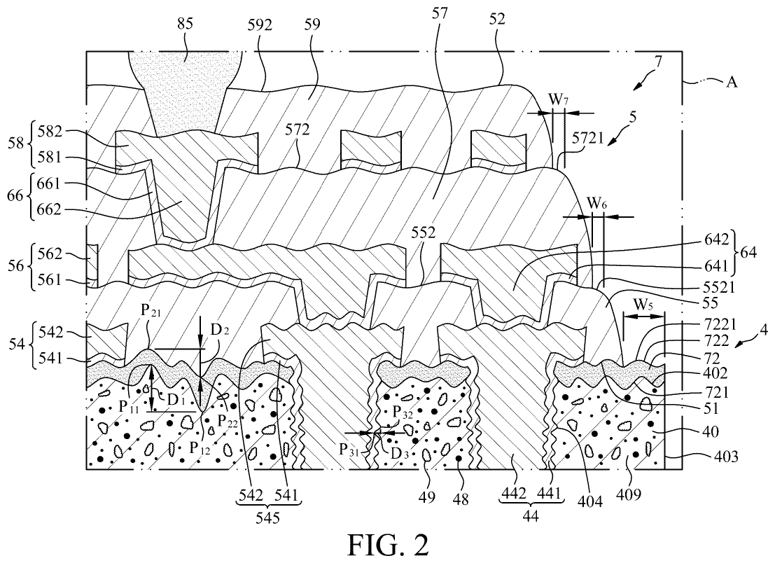

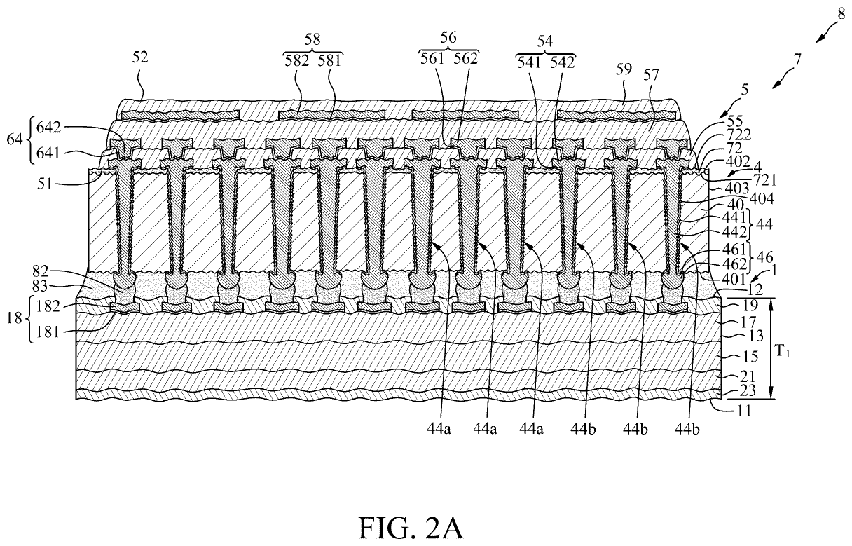

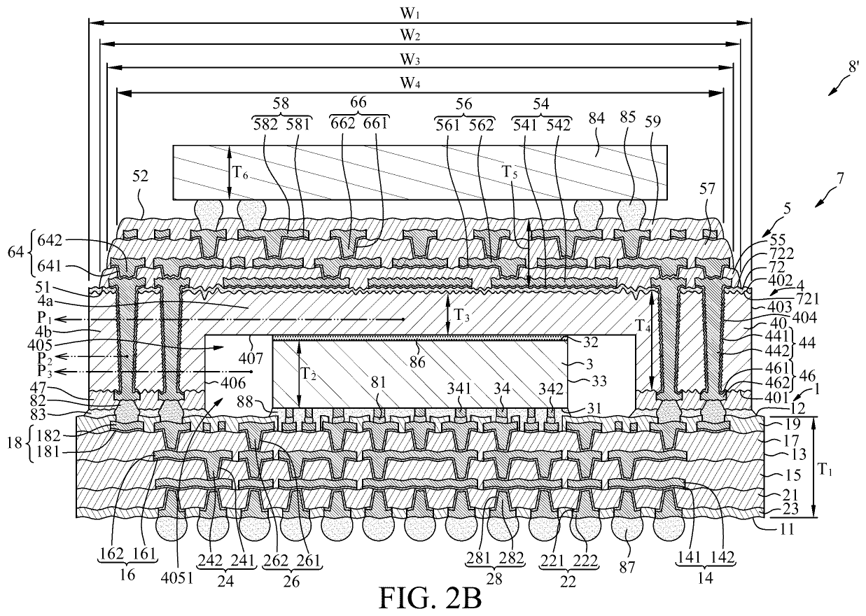

FIG. 1 illustrates a cross-sectional view of a package structure 8 according to some embodiments of the present disclosure. FIG. 2 illustrates an enlarged view of an area “A” of FIG. 1. FIG. 2A illustrates a cross-sectional view taken along line I-I in FIG. 1. The package structure 8 may be also referred to as “an electronic package” or a “semiconductor package structure”. The package structure 8 may include a lower circuit pattern structure 1, an electronic device 3, an assembly structure 7 (including a heat dissipating structure 4 and an upper circuit pattern structure 5), an electrical component 84 and a plurality of external connectors 87.

The lower circuit pattern structure 1 may be also referred to as “a substrate”, “a lower substrate”, “a lower wiring structure”, “a lower stacked structure”, “a lower conductive structure”, “a high-density circuit pattern structure”, “a high-density substrate”, “a high-density wiring structure”, “a high-density stacked structure”, “a high-density conductive structure”, “a first circuit pattern structure”, “a first substrate”, “a first wiring structure”, “a first stacked structure”, or “a first conductive structure”.

The lower circuit pattern structure 1 may include at least one dielectric layer (including, for example, a first dielectric layer 15, a second dielectric layer 17, a third dielectric layer 19, a fourth dielectric layer 21 and a fifth dielectric layer 23) and at least one circuit layer (including, for example, a first circuit layer 14, a second circuit layer 16, a third circuit layer 18 and a fourth circuit layer 22) in contact with the dielectric layer (e.g., the dielectric layers 15, 17, 19, 21, 23). In one embodiment, the lower circuit pattern structure 1 may be similar to a coreless substrate, and may be in a wafer type, a panel type or a strip type. The lower circuit pattern structure 1 may have a first surface 11 (e.g., a bottom surface), a second surface 12 (e.g., a top surface) opposite to the first surface 11 (e.g., the bottom surface), and a lateral surface 13 extending between the first surface 11 (e.g., the bottom surface) and the second surface 12 (e.g., the top surface). The lower circuit pattern structure 1 may have a first thickness T₁.

The lower circuit pattern structure 1 may include a plurality of dielectric layers (for example, the dielectric layers 15, 17, 19, 21, 23), a plurality of circuit layers (for example, the circuit layers 14, 16, 18, 22) and a plurality of inner vias (for example, the first inner via 24, the second inner via 26 and the third inner via 28). The dielectric layers 15, 17, 19, 21, 23 are stacked on one another. In one embodiment, a material of the first dielectric layer 15, the second dielectric layer 17 and the fourth dielectric layer 21 may be a passivation layer, and may include, or be formed from, a photoresist layer, a cured photosensitive material, a cured photoimageable dielectric (PID) material such as a polyamide (PA), an Ajinomoto build-up film (ABF), a bismaleimide-triazine (BT), a polypropylene (PP), a polyimide (PI), epoxy or polybenzoxazole (PBO), or a combination of two or more thereof. In one embodiment, a material of the third dielectric layer 19 and the fifth dielectric layer 23 may include a solder resist material. The material of the third dielectric layer 19 and the fifth dielectric layer 23 may be same as or different from the material of the first dielectric layer 15, the second dielectric layer 17 and the fourth dielectric layer 21. In addition, each of the circuit layers 14, 16, 18, 22 may include a plurality of traces and a plurality of pads. The circuit layers 14, 16, 18, 22 are electrically connected to one another through the inner vias 24, 26, 28. In some embodiments, the circuit layers 14, 16, 18, 22 may be also referred to as “first circuit layers 14, 16, 18, 22”. The dielectric layers 15, 17, 19, 21, 23 may be also referred to as “first dielectric layers 15, 17, 19, 21, 23”. The inner vias 24, 26, 28 may be also referred to as “first inner vias 24, 26, 28”.

The first circuit layer 14 may be a fan-out circuit layer, and a line width/line space (L/S) of the first circuit layer 14 may be less than or equal to 10 μm/10 μm, or less than or equal to 7 μm/ 7 μm. In one embodiment, the first circuit layer 14 may include a seed layer 141 and a conductive metal material 142 (e.g., copper) disposed on the seed layer 141. The first dielectric layer 15 may cover the first circuit layer 14. Thus, the first circuit layer 14 may be embedded in the first dielectric layer 15. A bottom surface of the first circuit layer 14 may be substantially coplanar with a bottom surface of the first dielectric layer 15. Thus, the bottom surface of the first circuit layer 14 may be exposed by the first dielectric layer 15.

The second circuit layer 16 may be a fan-out circuit layer, and a line width/line space (L/S) of the second circuit layer 16 may be less than or equal to 10 μm/10 μm, or less than or equal to 7 μm/7 μm. In one embodiment, the second circuit layer 16 may include a seed layer 161 and a conductive metal material 162 (e.g., copper) disposed on the seed layer 161. The second circuit layer 16 may be formed or disposed on the top surface of the first dielectric layer 15.

The first inner via 24 may be disposed in an opening of the first dielectric layer 15, and extend through the first dielectric layer 15 to contact and electrically connect the first circuit layer 14 and the second circuit layer 16. The first inner via 24 may include a seed layer 241 and a conductive metal material 242 (e.g., copper) disposed on the seed layer 241. In some embodiments, the second circuit layer 16 and the first inner via 24 may be formed integrally and concurrently. Thus, the seed layer 161 and the seed layer 241 may be the same layer. The conductive metal material 162 and the conductive metal material 242 may be the same layer. In addition, the first inner via 24 may taper downward. Thus, the first inner via 24 may taper away from the electronic device 3 and the upper circuit pattern structure 5.

The second dielectric layer 17 may cover the second circuit layer 16. Thus, the second circuit layer 16 may be embedded in the second dielectric layer 17. A bottom surface of the second circuit layer 16 may be substantially coplanar with a bottom surface of the second dielectric layer 17.

The third circuit layer 18 may be a fan-out circuit layer, and a line width/line space (L/S) of the third circuit layer 18 may be less than or equal to 10 μm/10 μm, or less than or equal to 7 μm/7 μm. In one embodiment, the third circuit layer 18 may include a seed layer 181 and a conductive metal material 182 (e.g., copper) disposed on the seed layer 181. The third circuit layer 18 may be formed or disposed on the top surface of the second dielectric layer 17.

The second inner via 26 may be disposed in an opening of the second dielectric layer 17, and extend through the second dielectric layer 17 to contact and electrically connect the second circuit layer 16 and the third circuit layer 18. The second inner via 26 may include a seed layer 261 and a conductive metal material 262 (e.g., copper) disposed on the seed layer 261. In some embodiments, the third circuit layer 18 and the second inner via 26 may be formed integrally and concurrently. Thus, the seed layer 181 and the seed layer 261 may be the same layer. The conductive metal material 182 and the conductive metal material 262 may be the same layer. In addition, the second inner via 26 may taper downward. Thus, the second inner via 26 may taper away from the electronic device 3 and the upper circuit pattern structure 5.

The third dielectric layer 19 may cover the third circuit layer 18. Thus, the third circuit layer 18 may be embedded in the third dielectric layer 19. A bottom surface of the third circuit layer 18 may be substantially coplanar with a bottom surface of the third dielectric layer 19. The third dielectric layer 19 may define a plurality of openings to expose portions (e.g., pads) of the third circuit layer 18.

The fourth dielectric layer 21 may cover the bottom surface of the first circuit layer 14 and the bottom surface of the first dielectric layer 15. The fourth circuit layer 22 may be a fan-out circuit layer, and a line width/line space (L/S) of the fourth circuit layer 22 may be less than or equal to 10 μm/10 μm, or less than or equal to 7 μm/7 μm. In one embodiment, the fourth circuit layer 22 may include a seed layer 221 and a conductive metal material 222 (e.g., copper) disposed on the seed layer 221. The fourth circuit layer 22 may be formed or disposed on the bottom surface of the fourth dielectric layer 21. In some embodiments, the fourth circuit layer 22 may include a plurality of pads.

The third inner via 28 may be disposed in an opening of the fourth dielectric layer 21, and extend through the fourth dielectric layer 21 to contact and electrically connect the first circuit layer 14 and the fourth circuit layer 22. The third inner via 28 may include a seed layer 281 and a conductive metal material 282 (e.g., copper) disposed on the seed layer 281. In some embodiments, the fourth circuit layer 22 and the third inner via 28 may be formed integrally and concurrently. Thus, the seed layer 221 and the seed layer 281 may be the same layer. The conductive metal material 222 and the conductive metal material 282 may be the same layer. In addition, the third inner via 28 may taper upward. Thus, the third inner via 28 may taper toward the electronic device 3 and the upper circuit pattern structure 5. A tapering direction of the third inner via 28 is different from a tapering direction of the first inner via 24.

The fifth dielectric layer 23 may surround the fourth circuit layer 22. Thus, the fourth circuit layer 22 may be embedded in the fifth dielectric layer 23. A bottom surface of the fourth circuit layer 22 may be substantially coplanar with a bottom surface of the fifth dielectric layer 23. Thus, the bottom surface of the fourth circuit layer 22 may be exposed by the fifth dielectric layer 23. As shown in FIG. 1, the top surfaces and the bottom surfaces of the dielectric layers 15, 17, 19, 21, 23 and the circuit layers 14, 16, 18, 22 may be wavy surfaces or uneven surfaces.

The electronic device 3 may be a semiconductor element, a semiconductor chip or a semiconductor die such as a logic die, an application processor (AP) die, an application specific integrated circuit (ASIC) die. The electronic device 3 may be disposed over and electrically connected to the second surface 12 (e.g., the top surface) of the lower circuit pattern structure 1 (e.g., the substrate 1). The electronic device 3 may be disposed between the lower circuit pattern structure 1 and the heat dissipating structure 4. The electronic device 3 may a first surface 31 (e.g., an active surface, a lower surface, or a bottom surface), a second surface 32 (e.g., a back side surface, an upper surface, or a top surface) opposite to the first surface 31, and a lateral surface 33 extending between the first surface 31 and the second surface 32. The first surface 31 of the electronic device 3 may face the second surface 12 (e.g., the top surface) of the lower circuit pattern structure 1. The electronic device 3 may have a second thickness T₂.

The electronic device 3 may include a plurality of bumps 34 extending beyond or protruding from the first surface 31. A material of the bumps 34 may be, for example, aluminum (Al), copper (Cu), tin (Sn), lead (Pb) or other suitable metals or alloy. In some embodiments, the bumps 34 of the electronic device 3 may be bonded to the exposed portions (e.g., exposed pads) of the third circuit layer 18 of the lower circuit pattern structure 1 through a plurality of bonding materials 81 such as solder material or reflowable material. A material of the bonding materials 81 may include silver-tin-alloy (AgSn). The bumps 34 may include a plurality of first bumps 341 and a plurality of second bumps 342. The second bumps 342 are closer to the lateral surface 33 of the electronic device 3 than the first bumps 341 are. A width of the second bump 342 is less than a width of the first bump 341. A pitch of the second bumps 342 is less than a pitch of the first bumps 341. An underfill 88 may be formed or disposed between the first surface 31 of the electronic device 3 and the second surface 12 (e.g., the top surface) of the lower circuit pattern structure 1 so as to cover and protect the joint formed by the bumps 34, the bonding materials 81 and the exposed portions (e.g., exposed pads) of the third circuit layer 18 of the lower circuit pattern structure 1.

The assembly structure 7 may include a heat dissipating structure 4, an upper circuit pattern structure 5, and a leveling layer 72 between the heat dissipating structure 4 and the upper circuit pattern structure 5. The heat dissipating structure 4 may be also referred to as “a reinforcement structure 4”. The heat dissipating structure 4 (e.g., the reinforcement structure 4) may be spaced apart from the lower circuit pattern structure 1 and may accommodate the electronic device 3. The heat dissipating structure 4 may include a heat dissipating portion 40 and a conductive portion 44. The heat dissipating portion 40 may be configured to guide a heat generated by the electronic device 3 to an outside of the package structure 8 during an operation of the electronic device 3. The conductive portion 44 may be electrically connected to the lower circuit pattern structure 1 (e.g., the substrate 1), and may extend through the heat dissipating portion 40. The heat dissipating portion 40 may be also referred to as “a main body 40”. The conductive portion 44 may include at least one electrical through via 44 overlapping the electronic device 3 in a direction parallel with a top surface 12 of the lower circuit pattern structure 1 (e.g., the substrate 1). Thus, the heat dissipating structure 4 may include a main body 40 and at least one electrical through via 44. In some embodiments, the heat dissipating structure 4 may include a plurality of electrical through vias 44. The electrical through via 44 may be an electrical conduction path and a heat conduction path. The electrical through via 44 may be also referred to as “a conductive through via”. The heat dissipating structure 4 may be disposed over the electronic device 3 and the lower circuit pattern structure 1 (e.g., the substrate 1), and may be attached to the electronic device 3. The heat dissipating structure 4 may be configured to dissipate a portion of a heat generated by the electronic device 3 and transmitted in the electrical through via 44.

The main body 40 may include an inorganic sintered material. The main body 40 may include a nonpolymeric material, a non-compound material, an electrical insulation material, and or a non-metallic material. The main body 40 does not include a molding compound or a resin material. A material of the main body 40 is different from a material of the electrical through via 44. For example, the main body 40 may include a porous structure. The main body 40 may also referred to as “a porous main body”, “a porous-structured main body” or “porous structure main body” . As shown in FIG. 2, the main body 40 may include a plurality of voids 49 and a plurality of fillers 48. For example, the main body 40 may include ceramic or glass, and the electrical through via 44 may include a conductive material, e.g., a metal such as copper (Cu). Thus, the main body 40 may include a brittle material. The main body 40 may be more brittle than the electrical through via 44. The main body 40 may not have an electrical function, and may include a nonconductive material. A rigidity and a hardness of the main body 40 may be greater than a rigidity and a hardness of the electrical through via 44. The main body 40 may be more rigid and harder than the electrical through via 44.

The main body 40 (e.g., the heat dissipating portion) may be a cap structure. The main body 40 (e.g., the heat dissipating portion) may have a first surface 401 (e.g., a bottom surface), a second surface 402 (e.g., a top surface) opposite to the first surface 401 and an outer lateral surface 403 extending between the first surface 401 and the second surface 402. The outer lateral surface 403 may be substantially perpendicular to the top surface 12 of the substrate 1. The first surface 401 (e.g., the bottom surface) of the main body 40 (e.g., the heat dissipating portion) may be a first surface (e.g., a bottom surface) of the heat dissipating structure 4, and may face the lower circuit pattern structure 1. The second surface 402 (e.g., the top surface) of the main body 40 (e.g., the heat dissipating portion) may be a second surface (e.g., a top surface) of the heat dissipating structure 4, and may face the upper circuit pattern structure 5.

The main body 40 (e.g., the heat dissipating portion) may include a first portion 4a (e.g., a main portion, a center portion or a thin portion) and a second portion 4b (e.g. a sidewall, a periphery portion or a thick portion) surrounding the first portion 4a. A thickness T₃ of the first portion 4a is less than a thickness T₄ of the second portion 4b. The first portion 4a and the second portion 4b may collectively define a cavity 405 recessed from the first surface 401 of the main body 40 (e.g., the heat dissipating portion). Thus, the main body 40 (e.g., the heat dissipating portion) may define the cavity 405 recessed from the first surface 401 of the main body 40 (e.g., the heat dissipating portion). The cavity 405 may be configured for accommodating the electronic device 3, and the electrical through via 44 may be disposed around the electronic device 3. The electrical through via 44 may be disposed in the second portion 4b (e.g., the sidewall 4b). The first portion 4a and the second portion 4b may be formed concurrently and integrally. Thus, there may be no interface between the first portion 4a and the second portion 4b. The main body 40 (e.g., the heat dissipating portion) may be a monolithic structure or a one-piece structure. The main body 40 (e.g., the heat dissipating portion) of the heat dissipating structure 4 may have a fourth thickness T₄ (e.g., the maximum thickness). The heat dissipating structure 4 may have the maximum thickness T₄ (e.g., the fourth thickness T₄).

The cavity 405 may include a top wall 407 and a sidewall 406. The top wall 407 may be a bottom surface of the first portion 4a, and may be also referred to as “a first inner surface”. The sidewall 406 may be a side surface of the second portion 4b, and may be also referred to as “a second inner surface”. The cavity 405 may accommodate the electronic device 3 and air. A width of the cavity 405 may be greater than a width of the electronic device 3. Thus, the lateral surface 33 of the electronic device 3 is spaced apart from the sidewall 406 of the cavity 405. An empty space 4051 is between the lateral surface 33 of the electronic device 3, the sidewall 406 of the cavity 405, the top wall 407 of the cavity 405, the second surface 12 (e.g., the top surface) of the lower circuit pattern structure 1 and an inner surface of the underfill 83. The empty space 4051 may be an enclosed space and may surround the electronic device 3. In addition, a thermal material 86 (e.g., a bonding material or a thermal interface material (TIM)) may be interposed between the second surface 32 of the electronic device 3 and the top wall 407 of the cavity 405.

The electrical through via(s) 44 may extend through the second portion 4b of the main body 40 (e.g., the heat dissipating portion). Thus, the electrical through via(s) 44 may be embedded in the main body 40 (e.g., the heat dissipating portion), and may extend from the second surface 402 (e.g., the top surface) of the main body 40 (e.g., the heat dissipating portion) to the first surface 401 (e.g., the bottom surface) of the main body 40 (e.g., the heat dissipating portion). In some embodiments, the main body 40 (e.g., the heat dissipating portion) may define at least one through hole 404 extending through the second portion 4b of the main body 40 (e.g., the heat dissipating portion). Thus, the through hole 404 may extend from the second surface 402 (e.g., the top surface) of the main body 40 (e.g., the heat dissipating portion) to the first surface 401 (e.g., the bottom surface) of the main body 40 (e.g., the heat dissipating portion).

In some embodiments, the electrical through via 44 and the through hole 404 may taper from the second surface 402 (e.g., the top surface) of the main body 40 (e.g., the heat dissipating portion) to the first surface 401 (e.g., the bottom surface) of the main body 40 (e.g., the heat dissipating portion). The electrical through via 44 and the through hole 404 may taper along a direction from the second surface 402 (e.g., the top surface) of the main body 40 (e.g., the heat dissipating portion) to the first surface 401 (e.g., the bottom surface) of the main body 40 (e.g., the heat dissipating portion). Thus, the electrical through via 44 and the through hole 404 may taper toward the lower circuit pattern structure 1, and may taper away from the upper circuit pattern structure 5. The electrical through via 44 may include a seed layer 441 disposed on a sidewall of the through hole 404 and a conductive metal material 442 (e.g., copper) disposed on the seed layer 441. The electrical through via(s) 44 may be electrically connected to the lower circuit pattern structure 1 and the upper circuit pattern structure 5. Thus, the lower circuit pattern structure 1 may be electrically connected to the upper circuit pattern structure 5 through the electrical through via(s) 44.

In some embodiments, the heat dissipating structure 4 may further include at least one electrical contact 46 (e.g., an electrical bump) disposed on the first surface of the heat dissipating structure 4 (i.e., the first surface 401 of the main body 40). The electrical contact 46 (e.g., the electrical bump) may contact the electrical through via 44. The electrical contact 46 may include a seed layer 461 disposed on the first surface of the heat dissipating structure 4 (i.e., the first surface 401 of the main body 40) and a conductive metal material 462 (e.g., copper) disposed on the seed layer 461. The electrical contact 46 and the electrical through via 44 may be formed concurrently and integrally. Thus, the seed layer 461 and the seed layer 441 may be the same layer. The conductive metal material 462 and the conductive metal material 442 may be the same layer. The electrical contact 46 may be a bottom portion of the electrical through via 44. The bottom portion of the electrical through via 44 may extend beyond the first surface of the heat dissipating structure 4 (i.e., the first surface 401 of the main body 40). There may be no interface between the electrical contact 46 and the electrical through via 44.

An outer surface of the electrical contact 46 may be a convex curved surface. In addition, the outer surface of the electrical contact 46 may be a wavy surface or an uneven surface since the electrical contact 46 may be formed from a metal paste such as a copper paste. In some embodiments, the electrical contact(s) 46 of the heat dissipating structure 4 may be bonded to the exposed portions (e.g., exposed pads) of the third circuit layer 18 of the lower circuit pattern structure 1 through a plurality of conductive bonding elements 82, e.g., bonding materials 82 such as solder material or reflowable material. Thus, the electrical through via(s) 44 and the electrical contact(s) 46 may be spaced apart from the lower circuit pattern structure 1, and may be electrically connected to the lower circuit pattern structure 1 through a solder material (e.g., the conductive bonding element 82). In addition, a width of the conductive bonding element 82 may be greater than a width of the bonding material 81.

A material of the bonding materials 82 may include silver-tin-alloy (AgSn). An underfill 83 may be formed or disposed between the first surface of the heat dissipating structure 4 (i.e., the first surface 401 of the main body 40) and the second surface 12 (e.g., the top surface) of the lower circuit pattern structure 1 so as to cover and protect the joint formed by the electrical contact(s) 46 and the bonding materials 82. A top portion of the underfill 83 may contact the outer lateral surface 403 of the main body 40 (e.g., the heat dissipating portion) and the sidewall 406 of the cavity 405 (e.g., the side surface of the second portion 4b).

Surface roughness is defined as the deviations from the mean surface level. For example, the surface roughness may include the three kinds of parameters: Ra, Rz and Ry. Surface roughness Ra is the arithmetical mean of the absolute values of the profile deviations from the mean surface level. Surface roughness Rz is the average value of the absolute values of the heights of five highest peaks and the depths of five deepest valleys. Surface roughness Ry (maximum height) is the vertical distance between the highest peak and the lowest valley. As shown in FIGS. 1 and 2, the surface roughness Ra, Rz, Ry of the second surface 402 (e.g., the top surface) of the main body 40 (e.g., the heat dissipating portion) may be different from the surface roughness Ra, Rz, Ry of the sidewall of the through hole 404 of the main body 40 (e.g., the heat dissipating portion), respectively. For example, the surface roughness Ra, Rz, Ry of the second surface 402 (e.g., the top surface) of the main body 40 (e.g., the heat dissipating portion) may be greater than or less than the surface roughness Ra, Rz, Ry of the sidewall of the through hole 404 of the main body 40 (e.g., the heat dissipating portion), respectively.

The surface roughness Ra, Rz, Ry of the second surface 402 (e.g., the top surface) of the main body 40 (e.g., the heat dissipating portion) of the heat dissipating structure 4 may be different from the surface roughness Ra, Rz, Ry of the outer lateral surface 403 of the main body 40 (e.g., the heat dissipating portion) of the heat dissipating structure 4, respectively. For example, the surface roughness Ra, Rz, Ry of the second surface 402 (e.g., the top surface) of the main body 40 (e.g., the heat dissipating portion) of the heat dissipating structure 4 may be greater than or less than the surface roughness Ra, Rz, Ry of the outer lateral surface 403 of the main body 40 (e.g., the heat dissipating portion) of the heat dissipating structure 4, respectively.

The leveling layer 72 may be interposed between the second surface 402 (e.g., the top surface) of the main body 40 (e.g., the heat dissipating portion) of the heat dissipating structure 4 and a bottom surface 51 of the upper circuit pattern structure 5. The leveling layer 72 may be configured to level the second surface 402 (e.g., the top surface) of the main body 40 (e.g., the heat dissipating portion). Alternatively, the leveling layer 72 may be configured to mitigate or compensate for the unevenness and roughness of the second surface 402 (e.g., the top surface) of the main body 40 (e.g., the heat dissipating portion) of the heat dissipating structure 4, so as to facilitate the formation of the upper circuit pattern structure 5 on the leveling layer 72 and on the second surface 402 (e.g., the top surface) of the main body 40 (e.g., the heat dissipating portion) of the heat dissipating structure 4.

In one embodiment, a material of the leveling layer 72 may include, or be formed from, a cured photosensitive material, a cured photoimageable dielectric (PID) material such as a polyamide (PA), an Ajinomoto build-up film (ABF), a bismaleimide-triazine (BT), a polypropylene (PP), a polyimide (PI), epoxy or polybenzoxazole (PBO), or a combination of two or more thereof. The leveling layer 72 may be also referred to as “an intermediate layer” or “an adhesion layer”. The leveling layer 72 does not include a horizontal electrical path therein. That is, there may be no horizontally extending circuit embedded in the leveling layer 72.

The leveling layer 72 may have a first surface 721 (e.g., a bottom surface) and a second surface 722 (e.g., a top surface) opposite to the first surface 721. The first surface 721 (e.g., the bottom surface) may contact the second surface 402 (e.g., the top surface) of the main body 40 (e.g., the heat dissipating portion). A surface roughness Ra, Rz, Ry of the second surface 722 of the leveling layer 72 may be less than a surface roughness Ra, Rz, Ry of the second surface 402 (e.g., the top surface) of the main body 40 (e.g., the heat dissipating portion) of the heat dissipating structure 4.

The upper circuit pattern structure 5 may be also referred to as “an upper substrate”, “an upper wiring structure”, “an upper stacked structure”, “an upper conductive structure”, “a low-density circuit pattern structure”, “a low-density substrate”, “a low-density wiring structure”, “a low-density stacked structure”, “a low-density conductive structure”, “a second circuit pattern structure”, “a second substrate”, “a second wiring structure”, “a second stacked structure”, or “a second conductive structure”.

The upper circuit pattern structure 5 may be attached to the heat dissipating structure 4 through the leveling layer 72. The upper circuit pattern structure 5 may be electrically connected to the lower circuit pattern structure 1 through the electrical through via(s) 44. The upper circuit pattern structure 5 may be formed or built up on the leveling layer 72. In one embodiment, the leveling layer 72 may be omitted, and the upper circuit pattern structure 5 may be formed or built up on the second surface 402 (e.g., the top surface) of the main body 40 (e.g., the heat dissipating portion).

The upper circuit pattern structure 5 may include at least one dielectric layer (including, for example, a first dielectric layer 55, a second dielectric layer 57 and a third dielectric layer 59) and at least one circuit layer (including, for example, a first circuit layer 54, a second circuit layer 56 and a third circuit layer 58) in contact with the dielectric layer (e.g., the dielectric layers 55, 57, 59). In one embodiment, the upper circuit pattern structure 5 may be similar to a coreless substrate, and may be in a wafer type, a panel type or a strip type. The upper circuit pattern structure 5 may have a first surface 51 (e.g., a bottom surface) and a second surface 52 (e.g., a top surface) opposite to the first surface 51 (e.g., the bottom surface). The upper circuit pattern structure 5 may have a fifth thickness T₅.

The upper circuit pattern structure 5 may include a plurality of dielectric layers (for example, the dielectric layers 55, 57, 59), a plurality of circuit layers (for example, the circuit layers 54, 56, 58) and a plurality of inner vias (for example, the first inner via 64 and the second inner via 66). The dielectric layers 55, 57, 59 are stacked on one another. In one embodiment, a material of the first dielectric layer 55, the second dielectric layer 57 and the third dielectric layer 59 may be a passivation layer, and may include, or be formed from, a photoresist layer, a cured photosensitive material, a cured photoimageable dielectric (PID) material such as a polyamide (PA), an Ajinomoto build-up film (ABF), a bismaleimide-triazine (BT), a polypropylene (PP), a polyimide (PI), epoxy or polybenzoxazole (PBO), or a combination of two or more thereof. In addition, each of the circuit layers 54, 56, 58 may include a plurality of traces and a plurality of pads. The circuit layers 54, 56, 58 are electrically connected to one another through the inner vias 64, 66. In some embodiments, the circuit layers 54, 56, 58 may be also referred to as “second circuit layers 54, 56, 58”. The dielectric layers 55, 57, 59 may be also referred to as “second dielectric layers 55, 57, 59”. The inner vias 64, 66 may be also referred to as “second inner vias 64, 66”. In some embodiments, the heat dissipating structure 4 may further include the upper circuit pattern structure 5. Thus, the heat dissipating structure 4 may further include the circuit layers 54, 56, 58 disposed on the main body 40 (e.g., the heat dissipating portion), and electrically connected to the lower circuit pattern structure 1 (e.g., the substrate 1) through the conductive portion 44.

The first circuit layer 54 may be a fan-out circuit layer, and a line width/line space (L/S) of the first circuit layer 54 may be less than or equal to 18 μm/ 18 μm, or less than or equal to 15 μm/ 15 μm. In one embodiment, the first circuit layer 54 may include a seed layer 541 and a conductive metal material 542 (e.g., copper) disposed on the seed layer 541. The first dielectric layer 55 may cover the first circuit layer 54. Thus, the first circuit layer 54 may be embedded in the first dielectric layer 55. A bottom surface of the first circuit layer 54 may be substantially coplanar with a bottom surface of the first dielectric layer 55. Thus, the bottom surface of the first circuit layer 54 may be exposed by the first dielectric layer 55.

The first circuit layer 54 may be the bottommost one of the plurality of circuit layers 54, 56, 58 of the upper circuit pattern structure 5. The first circuit layer 54 may include a pad 545. The pad 545 and the electrical through via 44 may be formed concurrently and integrally. The pad 545 may include a seed layer 541 and a conductive metal material 542 (e.g., copper) disposed on the seed layer 541. Thus, the seed layer 541 and the seed layer 441 may be the same layer. The conductive metal material 542 and the conductive metal material 442 may be the same layer. There may be no interface between the first circuit layer 54 (or the pad 545) and the electrical through via 44. In addition, the pad 545 may taper downward. Thus, the pad 545 may contact and taper toward the electrical through via 44 and the heat dissipating structure 4. Further, the electrical through via(s) 44 may extend through the leveling layer 72.

The second circuit layer 56 may be a fan-out circuit layer, and a line width/line space (L/S) of the second circuit layer 56 may be less than or equal to 18 μm/ 18 μm, or less than or equal to 15 μm/15 μm. In one embodiment, the second circuit layer 16 may include a seed layer 561 and a conductive metal material 562 (e.g., copper) disposed on the seed layer 561. The second circuit layer 56 may be formed or disposed on the top surface of the first dielectric layer 55.

The first inner via 64 may be disposed in an opening of the first dielectric layer 55, and extend through the first dielectric layer 55 to contact and electrically connect the first circuit layer 54 and the second circuit layer 56. The first inner via 64 may include a seed layer 641 and a conductive metal material 642 (e.g., copper) disposed on the seed layer 641. In some embodiments, the second circuit layer 56 and the first inner via 64 may be formed integrally and concurrently. Thus, the seed layer 561 and the seed layer 641 may be the same layer. The conductive metal material 562 and the conductive metal material 642 may be the same layer. In addition, the first inner via 64 may taper downward. Thus, the first inner via 64 may taper toward the heat dissipating structure 4.

The second dielectric layer 57 may cover the second circuit layer 56. Thus, the second circuit layer 56 may be embedded in the second dielectric layer 57. A bottom surface of the second circuit layer 56 may be substantially coplanar with a bottom surface of the second dielectric layer 57.

The third circuit layer 58 may be a fan-out circuit layer, and a line width/line space (L/S) of the third circuit layer 58 may be less than or equal to 18 μm/ 18 μm, or less than or equal to 15 μm/15 μm. In one embodiment, the third circuit layer 58 may include a seed layer 581 and a conductive metal material 582 (e.g., copper) disposed on the seed layer 581. The third circuit layer 58 may be formed or disposed on the top surface of the second dielectric layer 57.

The second inner via 66 may be disposed in an opening of the second dielectric layer 57, and extend through the second dielectric layer 57 to contact and electrically connect the second circuit layer 56 and the third circuit layer 58. The second inner via 66 may include a seed layer 661 and a conductive metal material 662 (e.g., copper) disposed on the seed layer 661. In some embodiments, the third circuit layer 58 and the second inner via 66 may be formed integrally and concurrently. Thus, the seed layer 581 and the seed layer 661 may be the same layer. The conductive metal material 582 and the conductive metal material 662 may be the same layer. In addition, the second inner via 66 may taper downward. Thus, the second inner via 66 may taper toward the heat dissipating structure 4.

The third dielectric layer 59 may cover the third circuit layer 58. Thus, the third circuit layer 58 may be embedded in the third dielectric layer 59. A bottom surface of the third circuit layer 58 may be substantially coplanar with a bottom surface of the third dielectric layer 59. The third dielectric layer 59 may define a plurality of openings to expose portions (e.g., pads) of the third circuit layer 58.

Each of the circuit layers 14, 16, 18, 22 of the lower circuit pattern structure 1 may be also referred to as “a high-density redistribution layer” or “a high-density circuit layer.” In some embodiments, a density of a circuit line (including, for example, a trace or a pad) of the high-density circuit layer (e.g., the circuit layers 14, 16, 18, 22 of the lower circuit pattern structure 1) is greater than a density of a circuit line of a low-density circuit layer (e.g., the circuit layers 54, 56, 58 of the upper circuit pattern structure 5). That is, the count of the circuit line (including, for example, a trace or a pad) in a unit area of the high-density circuit layers 14, 16, 18, 22 of the lower circuit pattern structure 1 is greater than the count of the circuit line in an equal unit area of the low-density circuit layers 54, 56, 58 of the upper circuit pattern structure 5, such as about 1.2 times or greater, about 1.5 times or greater, or about 2 times or greater. Alternatively, or in combination, a line space/line width (L/S) of the high-density circuit layers 14, 16, 18, 22 of the lower circuit pattern structure 1 is less than an L/S of the low-density circuit layers 54, 56, 58 of the upper circuit pattern structure 5, such as about 90% or less, about 50% or less, or about 20% or less. An L/S of one of the circuit layers 54, 56, 58 of the upper circuit pattern structure 5 is greater than an L/S of one of the circuit layers 14, 16, 18, 22 of the lower circuit pattern structure 1.

In some embodiments, the material of the leveling layer 72 may be different from the material of the dielectric layers 55, 57, 59 of the upper circuit pattern structure 5. Further, the first circuit layer 54 of the upper circuit pattern structure 5 may be formed on the leveling layer 72. Thus, the first circuit layer 54 of the upper circuit pattern structure 5 and the first surface 51 (e.g., the bottom surface) of the upper circuit pattern structure 5 may be substantially conformal with the second surface 722 (e.g., the top surface) of the leveling layer 72. In one embodiment, the leveling layer 72 may be omitted, and the first circuit layer 54 of the upper circuit pattern structure 5 may be formed on the second surface 402 (e.g., the top surface) of the main body 40 (e.g., the heat dissipating portion) of the heat dissipating structure 4. Thus, the first circuit layer 54 of the upper circuit pattern structure 5 and the first surface 51 (e.g., the bottom surface) of the upper circuit pattern structure 5 may be substantially conformal with the second surface 402 (e.g., the top surface) of the main body 40 (e.g., the heat dissipating portion) of the heat dissipating structure 4. The upper circuit pattern structure 5 may be disposed on the second surface 402 (e.g., the top surface) of the heat dissipating portion 40 of the heat dissipating structure 4. The first surface 51 (e.g., the bottom surface) of the circuit pattern structure 5 may be substantially conformal with the top surface 402 of the heat dissipating portion 40.

In some embodiments, the material of the main body 40 (e.g., the heat dissipating portion) of the heat dissipating structure 4 may be different from the material of the dielectric layers 55, 57, 59 of the upper circuit pattern structure 5. A thermal conductivity of the main body 40 (e.g., the heat dissipating portion) of the heat dissipating structure 4 is greater than a thermal conductivity of the dielectric layers 55, 57, 59 of the upper circuit pattern structure 5 and a thermal conductivity of the dielectric layers 15, 17, 19, 21, 23 of the lower circuit pattern structure 1. A conventional molding compound may have a thermal conductivity of 0.8˜1 W/mK. The thermal conductivity of the main body 40 (e.g., the heat dissipating portion) of the heat dissipating structure 4 may be greater than 0.8 W/mK, 1 W/mK, 1.2 W/mK, 1.5 W/mK, 2 W/mK, or 3 W/mK.

A rigidity and a hardness of the main body 40 (e.g., the heat dissipating portion) of the heat dissipating structure 4 is greater than a rigidity and a hardness of the dielectric layers 55, 57, 59 of the upper circuit pattern structure 5 and a rigidity and a hardness of the dielectric layers 15, 17, 19, 21, 23 of the lower circuit pattern structure 1. The rigidity and the hardness of the main body 40 (e.g., the heat dissipating portion) of the heat dissipating structure 4 is greater than a rigidity and a hardness of the circuit layers 14, 16, 18, 22 of the lower circuit pattern structure 1 and a rigidity and a hardness of the circuit layers 54, 56, 58 of the upper circuit pattern structure 5. The surface roughness Ra, Rz, Ry of the second surface 402 (e.g., the top surface) of the main body 40 (e.g., the heat dissipating portion) of the heat dissipating structure 4 is greater than a surface roughness Ra, Rz, Ry of a top surface of any one of the circuit layers 54, 56, 58 and a surface roughness Ra, Rz, Ry of a top surface of any one of the dielectric layers 55, 57, 59 of the upper circuit pattern structure 5.

As shown in FIG. 2, a vertical distance D₁ between the highest peak P₁₁ and the lowest valley P₁₂ of the second surface 402 (e.g., the top surface) of the main body 40 (e.g., the heat dissipating portion) is defines as the surface roughness Ry of the second surface 402 (e.g., the top surface) of the main body 40 (e.g., the heat dissipating portion). A vertical distance D₂ between the highest peak P₂₁ and the lowest valley P₂₂ of the second surface 722 of the leveling layer 72 is defines as the surface roughness Ry of the second surface 722 of the leveling layer 72. A distance D₃ between the highest peak P₃₁ and the lowest valley P₃₂ of the sidewall of the through hole 404 of the main body 40 (e.g., the heat dissipating portion) is defines as the surface roughness Ry of the sidewall of the through hole 404 of the main body 40 (e.g., the heat dissipating portion).

The surface roughness Ry (i.e., the vertical distance D₁) of the second surface 402 (e.g., the top surface) of the main body 40 (e.g., the heat dissipating portion) is greater than the surface roughness Ry (i.e., the vertical distance D₂) of the second surface 722 of the leveling layer 72. The surface roughness Ry (i.e., the vertical distance D₂) of the second surface 722 of the leveling layer 72 is greater than the surface roughness Ry (i.e., the vertical distance D₃) of the sidewall of the through hole 404 of the main body 40 (e.g., the heat dissipating portion). For example, the surface roughness Ry (i.e., the vertical distance D₁) of the second surface 402 (e.g., the top surface) of the main body 40 (e.g., the heat dissipating portion) may be 10 μm to 20 μm. The surface roughness Ry (i.e., the vertical distance D₂) of the second surface 722 of the leveling layer 72 may be less than 10 μm.

In addition, a surface roughness Ra, Rz, Ry of a second surface 552 (e.g., a top surface) of the first dielectric layer 55 of the upper circuit pattern structure 5 is less than the surface roughness Ra, Rz, Ry of the second surface 722 of the leveling layer 72. A surface roughness Ra, Rz, Ry of a second surface 572 (e.g., a top surface) of the second dielectric layer 57 of the upper circuit pattern structure 5 is less than the surface roughness Ra, Rz, Ry of the second surface 552 (e.g., the top surface) of the first dielectric layer 55. A surface roughness Ra, Rz, Ry of a second surface 592 (e.g., a top surface) of the third dielectric layer 59 of the upper circuit pattern structure 5 is less than the surface roughness Ra, Rz, Ry of the second surface 572 (e.g., the top surface) of the second dielectric layer 57 of the upper circuit pattern structure 5. For example, the surface roughness Ry of the second surface 552 (e.g., the top surface) of the first dielectric layer 55 may be less than 8 μm or less than 6 μm. The surface roughness Ry of the second surface 572 (e.g., a top surface) of the second dielectric layer 57 may be less than 6 μm or less than 4 μm. The surface roughness Ry of the second surface 592 (e.g., the top surface) of the third dielectric layer 59 may be less than 4 μm or less than 2 μm.

As shown in FIG. 1, the main body 40 (e.g., the heat dissipating portion) of the heat dissipating structure 4 has a first width W₁. The first dielectric layer 55 has a second width W₂. The second dielectric layer 57 has a third width W₃. The third dielectric layer 59 has a fourth width W₄. The fourth width W₄ of the third dielectric layer 59 is less than the third width W₃ of the second dielectric layer 57. The third width W₃ of the second dielectric layer 57 is less than the second width W₂ of the first dielectric layer 55. The second width W₂ of the first dielectric layer 55 is less than the first width W₁ of the main body 40 (e.g., the heat dissipating portion) of the heat dissipating structure 4. The dielectric layers 55, 57, 59 of the upper circuit pattern structure 5 have different widths W₂, W₃, W₄. In addition, a width of the lower circuit pattern structure 1 is greater than the first width W₁ of the main body 40 (e.g., the heat dissipating portion) of the heat dissipating structure 4 and a width of the upper circuit pattern structure 5 (e.g., the second width W₂ of the first dielectric layer 55).

As shown in FIG. 2, a portion 409 of the main body 40 (e.g., the heat dissipating portion) of the heat dissipating structure 4 may be disposed outside a vertical projection of the upper circuit pattern structure 5. A portion 7221 (or a region) of the second surface 722 (e.g., the top surface) of the leveling layer 72 is exposed by the first dielectric layer 55 of the upper circuit pattern structure 5. The portion 7221 is not covered by the first dielectric layer 55 of the upper circuit pattern structure 5. The portion 7221 has a fifth width W₅. In addition, a portion of the first dielectric layer 55 may be disposed outside a vertical projection of the second dielectric layer 57. A portion 5521 (or a region) of the second surface 552 (e.g., the top surface) of the first dielectric layer 55 is exposed by the second dielectric layer 57. The portion 5521 is not covered by the second dielectric layer 57. The portion 5521 has a sixth width W₆. In addition, a portion of the second dielectric layer 57 may be disposed outside a vertical projection of the third dielectric layer 59. A portion 5721 (or a region) of the second surface 572 (e.g., the top surface) of second dielectric layer 57 is exposed by the third dielectric layer 59. The portion 5721 is not covered by the third dielectric layer 59. The portion 5721 has a seventh width W₇. The fifth width W₅ of the portion 7221 is greater than the sixth width W₆ of the portion 5521. The sixth width W₆ of the portion 5521 is greater than the seventh width W₇ of the portion 5721.

As shown in FIG. 1, the electrical component 84 may be a second electronic device, a semiconductor element, a semiconductor chip or a semiconductor die such as a memory die or a memory chip. The electrical component 84 may be disposed over and electrically connected to the second surface 52 (e.g., the top surface) of the upper circuit pattern structure 5. Thus, the electrical component 84 (e.g., the second electronic device) may be disposed over the circuit layers 54, 56, 58. The electrical component 84 (e.g., the second electronic device) may be disposed over the heat dissipating structure 4 (e.g., the reinforcement structure 4), and may be electrically connected to the lower circuit pattern structure 1 through the electrical through via 44. The electrical component 84 may have a sixth thickness T₆. In some embodiments, the electrical component 84 may be bonded to the exposed portions (e.g., exposed pads) of the third circuit layer 58 of the upper circuit pattern structure 5 through a plurality of bonding materials 85 such as solder material or reflowable material. A material of the bonding materials 85 may include silver-tin-alloy (AgSn).

The external connectors 87 may be disposed adjacent to the first surface 11 (e.g., the bottom surface) of the lower circuit pattern structure 1. The external connectors 87 may be disposed on the fourth circuit layer 22 of the lower circuit pattern structure 1. The external connectors 87 may include a solder material or a reflowable material such as silver-tin-alloy (AgSn).

The fourth thickness T₄ of the main body 40 (e.g., the heat dissipating portion) of the heat dissipating structure 4 (i.e., the fourth thickness T₄ of the heat dissipating structure 4) may be greater than the first thickness T₁ of the lower circuit pattern structure 1, the second thickness T₂ of the electronic device 3, the fifth thickness T₅ of the upper circuit pattern structure 5 and the sixth thickness T₆ of the electrical component 84. The second thickness T₂ of the electronic device 3 may be greater than the fifth thickness T₅ of the upper circuit pattern structure 5 and the sixth thickness T₆ of the electrical component 84.

As shown in FIG. 2A, the electrical through vias 44 may include a plurality of first electrical through vias 44a and a plurality of second electrical through vias 44b. The second electrical through vias 44b are closer to the outer lateral surface 403 of the main body 40 (e.g., the heat dissipating portion) than the first electrical through vias 44a are. The second electrical through vias 44b are disposed around the first electrical through vias 44a. A width of the second electrical through via 44b may be less than a width of the first electrical through via 44a. A pitch of the second electrical through vias 44b may be less than a pitch of the first electrical through vias 44a.

In the embodiment illustrated in FIG. 1, a first portion of a heat generated by the electronic device 3 is conducted into the first portion 4a of the main body 40 (e.g., the heat dissipating portion) through the thermal material 86, and is then conducted to the outer lateral surface 403 of the main body 40 (e.g., the heat dissipating portion) horizontally and laterally through a first thermal path P₁. The first thermal path P₁ extends in a direction parallel with the top surface 12 of the substrate 1, and extends through the outer lateral surface 403 of the heat dissipating portion 40. The heat dissipating portion 40 is configured to guide the heat generated by the electronic device 3 to the outside of the package structure 8 along the first thermal path P₁. Thus, the heat dissipating portion 40 is configured to guide the heat generated by the electronic device 3 along the thermal path P₁ extending in a direction parallel with the top surface 12 of the substrate 1 to the outside of the package structure 8. In some embodiments, the first thermal path P₁ may extend through the conductive portion 44.

A second portion of the heat generated by the electronic device 3 is conducted from the lower circuit pattern structure 1 to the upper circuit pattern structure 5 through the electrical through via(s) 44. A portion of the second portion of the heat is then conducted to the outer lateral surface 403 of the main body 40 (e.g., the heat dissipating portion) horizontally and laterally through a second thermal path P₂. A third portion of the heat generated by the electronic device 3 is conducted into the empty space 4051, and is then conducted to the outer lateral surface 403 of the main body 40 (e.g., the heat dissipating portion) horizontally and laterally through a third thermal path P₃. Compared with a conventional molding compound or a conventional encapsulant, the main body 40 (e.g., the heat dissipating portion) has a relatively high thermal conductivity. Thus, the main body 40 (e.g., the heat dissipating portion) may be configured to dissipate the first portion and the third portion of the heat generated by the electronic device 3 and the portion of the second portion of the heat in the electrical through via(s) 44 to the outer lateral surface 403 of the main body 40 (e.g., the heat dissipating portion) horizontally and laterally. Thus, the working temperature of the package structure 8 during operation of the electronic device 3 may be reduced.

In addition, compared with the conventional molding compound, the conventional encapsulant and a conventional cavity interposer, the main body 40 (e.g., the heat dissipating portion) has a relatively high rigidity. Thus, the main body 40 (e.g., the heat dissipating portion) may have a larger thickness T₄, and may have no warpage. Accordingly, the second thickness T₂ of the electronic device 3 may be larger. That is, a thicker electronic device 3 having a larger second thickness T₂ may be used in the package structure 8. Such thicker electronic device 3 may have a thickness of greater than 300 μm, and will have a low risk of being broken during its manufacturing process. Thus, the manufacturing cost may be reduced.

In addition, the main body 40 of the reinforcement structure 4 has a relatively high rigidity. For example, the rigidity of the main body 40 of the reinforcement structure 4 is greater than a rigidity of the lower circuit pattern structure 1. Further, a coefficient of thermal expansion (CTE) of the main body 40 of the reinforcement structure 4 is less than a CTE of the lower circuit pattern structure 1. The CTE of the main body 40 of the reinforcement structure 4 is less than a CTE of the electrical through via 44 of the reinforcement structure 4. Thus, the main body 40 of the reinforcement structure 4 may be configured to reduce a warpage or a bending of the lower circuit pattern structure 1 during a thermal process.

FIG. 2B illustrates a cross-sectional view of a package structure 8′ according to some embodiments of the present disclosure. The package structure 8′ of FIG. 2B is similar to the package structure 8 of FIG. 1, and the differences are described as follows.

The electrical contact 46 may have a substantially square shape. The heat dissipating structure 4 may further include a bottom dielectric layer 47 disposed on the first surface 401 (e.g., the bottom surface) of the main body 40 (e.g., the heat dissipating portion). A material of the bottom dielectric layer 47 may be the same as the material of the dielectric layers 55, 57, 59 of the upper circuit pattern structure 5. The bottom dielectric layer 47 may define at least one opening to expose the electrical contact 46. The bonding material 82 may be formed or disposed in the opening of the bottom dielectric layer 47 to contact the electrical contact 46. The underfill 83 may be formed or disposed between the bottom dielectric layer 47 of the heat dissipating structure 4 and the second surface 12 (e.g., the top surface) of the lower circuit pattern structure 1. The underfill 83 may not contact the electrical contact 46.

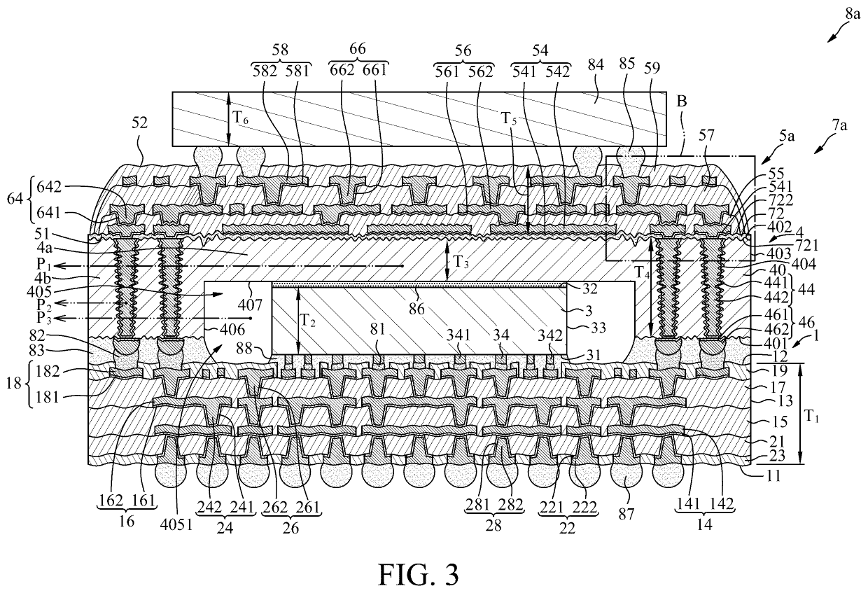

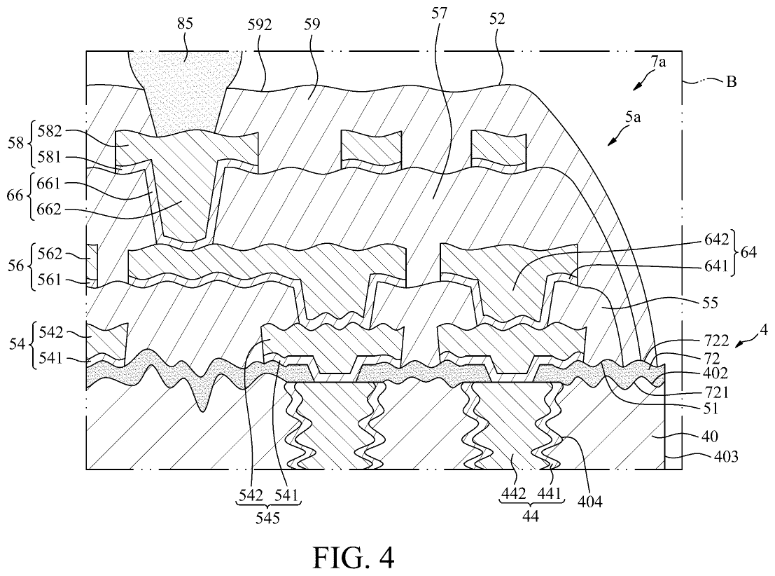

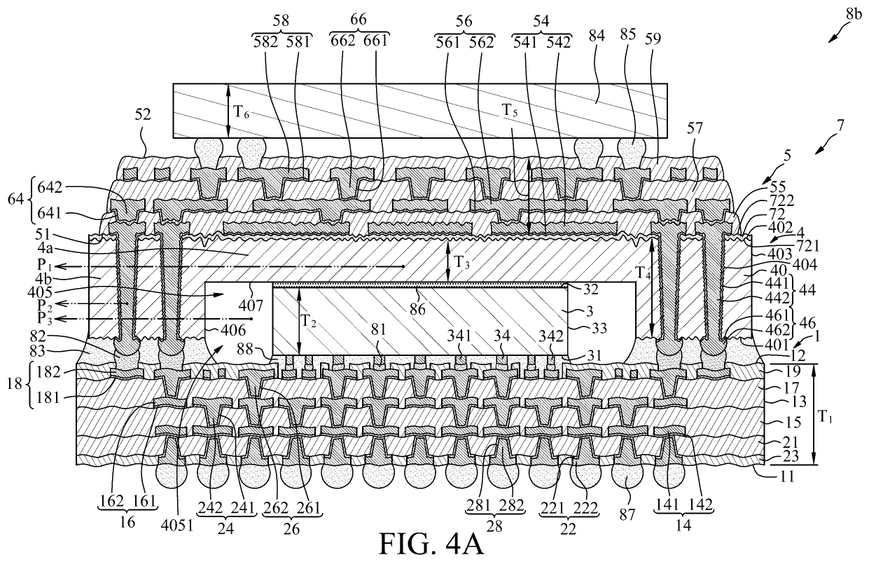

FIG. 3 illustrates a cross-sectional view of a package structure 8a according to some embodiments of the present disclosure. FIG. 4 illustrates an enlarged view of an area “B” of FIG. 3. The package structure 8a of FIG. 3 and FIG. 4 is similar to the package structure 8 of FIG. 1 and FIG. 2, and the differences are described as follows.

As shown in FIG. 3, the assembly structure 7a may include a heat dissipating structure 4, an upper circuit pattern structure 5a and a leveling layer 72 between the heat dissipating structure 4 and the upper circuit pattern structure 5a. The lateral surface 13 of the lower circuit pattern structure 1 may be aligned with the outer lateral surface 403 of the main body 40 (e.g., the heat dissipating portion) of the heat dissipating structure 4. Thus, a width of the lower circuit pattern structure 1 may be substantially equal to a width of the main body 40 (e.g., the heat dissipating portion) of the heat dissipating structure 4.

The bottom surface of the first circuit layer 54 or the bottom surface of the pad 545 (i.e., the bottom surface of the seed layer 541) of the upper circuit pattern structure 5a may cover and contact the top surface of the electrical through via 44. Thus, the first circuit layer 54 (or the pad 545) and the electrical through via 44 may be not formed concurrently and integrally. The seed layer 541 and the seed layer 441 may be different layers. The conductive metal material 542 and the conductive metal material 442 may be different layers. There may be an interface between the first circuit layer 54 (or the pad 545) and the electrical through via 44. In some embodiments, a portion of the pad 545 may extend through the leveling layer 72 to contact the electrical through via 44. The portion of the pad 545 may taper toward the electrical through via 44.

The top surface of the electrical contact 46 (i.e., the top surface of the seed layer 461) may cover and contact the bottom surface of the electrical through via 44. Thus, the electrical contact 46 and the electrical through via 44 may be not formed concurrently and integrally. The seed layer 461 and the seed layer 441 may be different layers. The conductive metal material 462 and the conductive metal material 442 may be different layers. There may be an interface between the electrical contact 46 and the electrical through via 44.

As shown in FIG. 3 and FIG. 4, in the upper circuit pattern structure 5a, the second dielectric layer 57 may cover and contact a lateral surface of the first dielectric layer 55, and may contact the second surface 722 (e.g., the top surface) of the leveling layer 72. In addition, the third dielectric layer 59 may cover and contact a lateral surface of the second dielectric layer 57, and may contact the second surface 722 (e.g., the top surface) of the leveling layer 72. Thus, the width of the third dielectric layer 59 is greater than the width of the second dielectric layer 57. The width of the second dielectric layer 57 is greater than the width of the first dielectric layer 55.

As shown in FIG. 3 and FIG. 4, the surface roughness Ra, Rz, Ry of the sidewall of the through hole 404 of the main body 40 (e.g., the heat dissipating portion) may be greater than the surface roughness Ra, Rz, Ry of the second surface 722 (e.g., the top surface) of the leveling layer 72 and/or the surface roughness Ra, Rz, Ry of the second surface 402 (e.g., the top surface) of the main body 40 (e.g., the heat dissipating portion).

FIG. 4A illustrates a cross-sectional view of a package structure 8b according to some embodiments of the present disclosure. As shown in FIG. 4A, the second inner via(s) 64, 66 connects to the second circuit layer(s) 54, 56, 58. The first inner via(s) 24, 26, 28 connect to the first circuit layer(s) 14, 16, 18. A line width/line space (L/S) of the second circuit layer(s) 54, 56, 58 is greater than an L/S of the first circuit layer(s) 14, 16, 18. A thickness of the second circuit layer(s) 54, 56, 58 is greater than a thickness of the first circuit layer(s) 14, 16, 18. A width of the second inner via(s) 64, 66 is greater than a width of the first inner via(s) 24, 26, 28. In addition, a tapering direction of the electrical through via 44 is the same as a tapering direction of the second inner via(s) 64, 66.

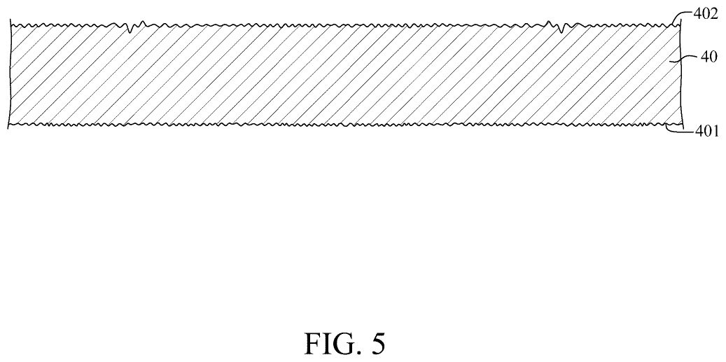

FIG. 5 through FIG. 20 illustrate a method for manufacturing a package structure according to some embodiments of the present disclosure. In some embodiments, the method is for manufacturing the package structure 8 shown in FIG. 1. FIG. 5 through FIG. 13 illustrate a method for manufacturing an assembly structure according to some embodiments of the present disclosure. In some embodiments, the method is for manufacturing the assembly structure 7 shown in FIG. 1.

Referring to FIG. 5, a main body 40 may be provided. The main body 40 may include an inorganic sintered material. The main body 40 may include a nonpolymeric material, a non-compound material, an electrical insulation material, and or a non-metallic material. The main body 40 does not include a molding compound or a resin material. For example, the main body 40 may include ceramic or glass. Thus, the main body 40 may include a brittle and rigid material. The main body 40 may have a first surface 401 (e.g., a bottom surface) and a second surface 402 (e.g., a top surface).

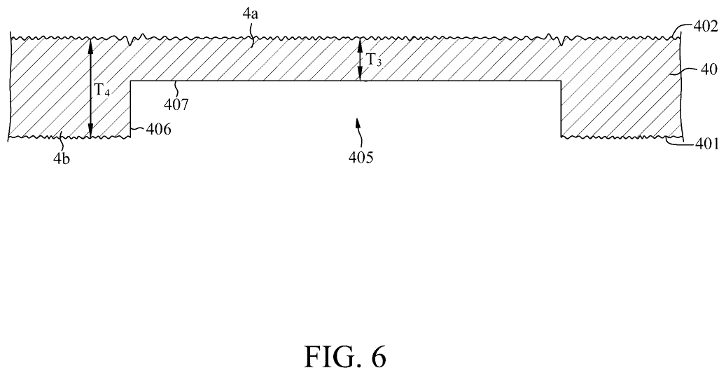

Referring to FIG. 6, a cavity 405 recessed from the first surface 401 of the main body 40 may be formed. The cavity 405 may be formed before the main body 40 is sintered. The main body 40 may include a first portion 4a (e.g., a center portion or a thin portion) and a second portion 4b (e.g. a periphery portion or a thick portion) surrounding the first portion 4a. A thickness T₃ of the first portion 4a is less than a thickness T₄ of the second portion 4b. Thus, the main body 40 may be a cap structure. The main body 40 (e.g., the heat dissipating portion) may be a monolithic structure or a one-piece structure. The cavity 405 may include a top wall 407 and a sidewall 406. The top wall 407 may be a bottom surface of the first portion 4a, and may be also referred to as “a first inner surface”. The sidewall 406 may be a side surface of the second portion 4b, and may be also referred to as “a second inner surface”.

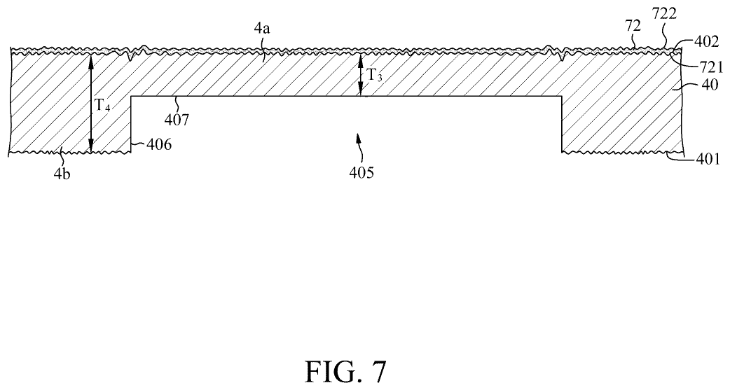

Referring to FIG. 7, a leveling layer 72 may be formed or disposed on the second surface 402 (e.g., the top surface) of the main body 40 (e.g., the heat dissipating portion). The leveling layer 72 may be configured to level the second surface 402 (e.g., the top surface) of the main body 40 (e.g., the heat dissipating portion). The leveling layer 72 does not include a horizontal electrical path therein. That is, there may be no horizontally extending circuit embedded in the leveling layer 72. The leveling layer 72 may have a first surface 721 (e.g., a bottom surface) and a second surface 722 (e.g., a top surface) opposite to the first surface 721. The first surface 721 (e.g., the bottom surface) may contact the second surface 402 (e.g., the top surface) of the main body 40 (e.g., the heat dissipating portion). A surface roughness Ra, Rz, Ry of the second surface 722 of the leveling layer 72 may be less than a surface roughness Ra, Rz, Ry of the second surface 402 (e.g., the top surface) of the main body 40.

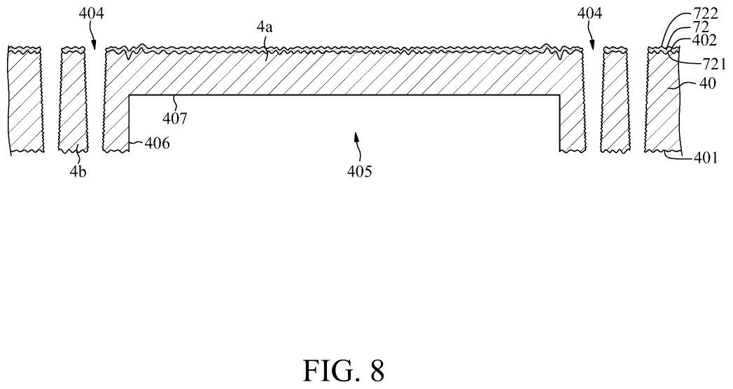

Referring to FIG. 8, at least one through hole 404 may be formed to extend through the leveling layer 72 and the second portion 4b of the main body 40 (e.g., the heat dissipating portion) by laser drilling. In some embodiments, the through hole 404 may taper from the second surface 402 (e.g., the top surface) of the main body 40 (e.g., the heat dissipating portion) to the first surface 401 (e.g., the bottom surface) of the main body 40 (e.g., the heat dissipating portion).

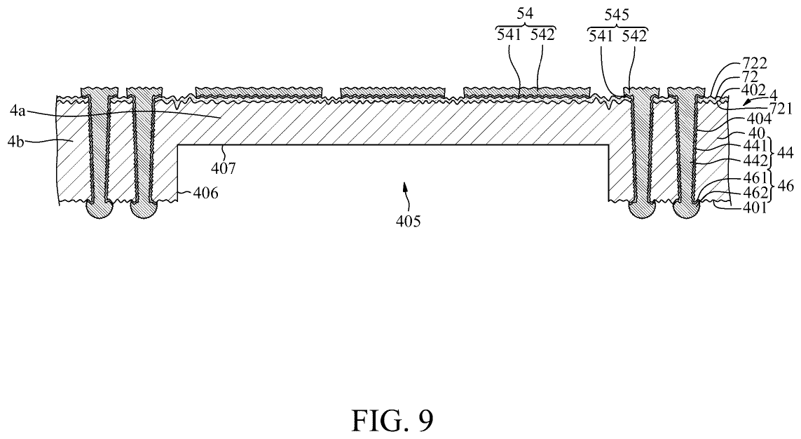

Referring to FIG. 9, a first circuit layer 54 (including a plurality of traces and a plurality of pads 545) may be formed on the leveling layer 72. Thus, the first circuit layer 54 may be substantially conformal with the second surface 722 (e.g., the top surface) of the leveling layer 72. In one embodiment, the leveling layer 72 may be omitted, and the first circuit layer 54 may be formed on the second surface 402 (e.g., the top surface) of the main body 40 (e.g., the heat dissipating portion). Thus, the first circuit layer 54 may be substantially conformal with the second surface 402 (e.g., the top surface) of the main body 40. The first circuit layer 54 may include a seed layer 541 and a conductive metal material 542 (e.g., copper) disposed on the seed layer 541.

At least one electrical through via 44 may be formed or disposed in the through hole 404 by, for example, electroplating or filling a metal paste. The metal paste may be copper paste. The electrical through via 44 may include a seed layer 441 disposed on a sidewall of the through hole 404 and a conductive metal material 442 (e.g., copper) disposed on the seed layer 441. The electrical through via(s) 44 may extend through the second portion 4b of the main body 40 (e.g., the heat dissipating portion). In some embodiments, the electrical through via 44 may taper from the second surface 402 (e.g., the top surface) of the main body 40 (e.g., the heat dissipating portion) to the first surface 401 (e.g., the bottom surface) of the main body 40 (e.g., the heat dissipating portion).

At least one electrical contact 46 may be formed or disposed on the first surface 401 (e.g., the bottom surface) of the main body 40 (e.g., the heat dissipating portion). The electrical contact 46 may contact the electrical through via 44. The electrical contact 46 may include a seed layer 461 disposed on the first surface 401 of the main body 40 and a conductive metal material 462 (e.g., copper) disposed on the seed layer 461. The first circuit layer 54 (including the pads 545), the electrical contact 46 and the electrical through via 44 may be formed concurrently and integrally. Thus, the seed layers 541, 461, 441 may be the same layer. The conductive metal material 542, 462, 442 may be the same layer.

Meanwhile, a heat dissipating structure 4 including the main body 40 and the electrical through via 44 is obtained.

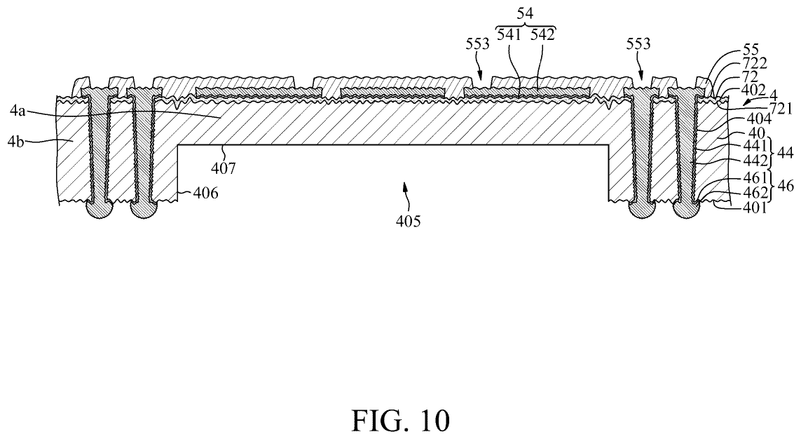

Referring to FIG. 10, a first dielectric layer 55 may be formed on the leveling layer 72 to cover the first circuit layer 54. The first dielectric layer 55 may define a plurality of openings 553 to expose portions of the first circuit layer 54.

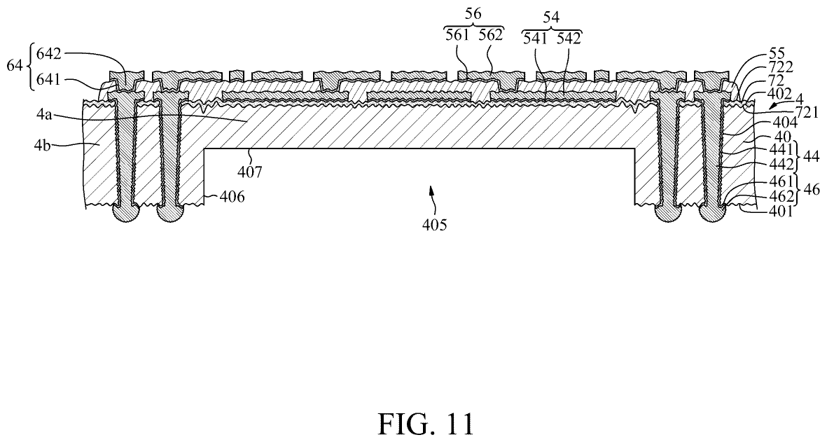

Referring to FIG. 11, a second circuit layer 56 may be formed or disposed on the first dielectric layer 55. At least one first inner via 64 may be formed or disposed in the opening 553 of the first dielectric layer 55, and may contact and electrically connect the first circuit layer 54 and the second circuit layer 56. The first inner via 64 may include a seed layer 641 and a conductive metal material 642 (e.g., copper) disposed on the seed layer 641. In some embodiments, the second circuit layer 56 and the first inner via 64 may be formed integrally and concurrently. Thus, the seed layer 561 and the seed layer 641 may be the same layer. The conductive metal material 562 and the conductive metal material 642 may be the same layer. In addition, the first inner via 64 may taper downward. Thus, the first inner via 64 may taper toward the main body 40 (e.g., the heat dissipating portion).

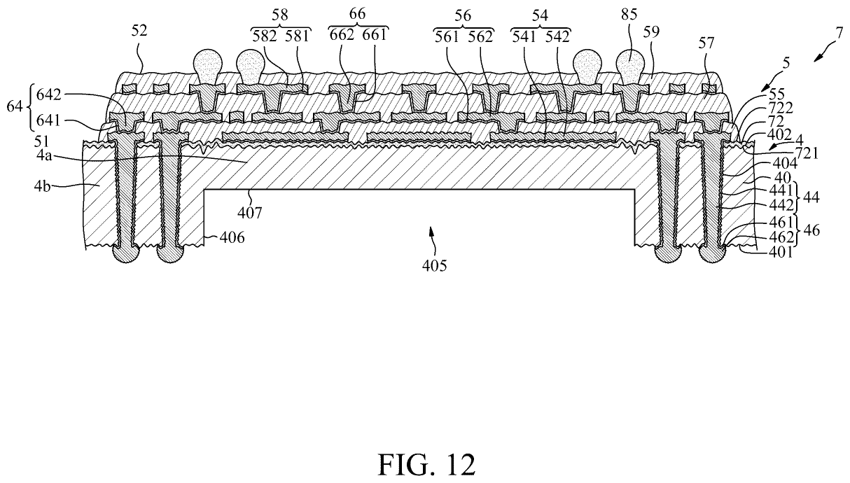

Referring to FIG. 12, a second dielectric layer 57 may be formed on the first dielectric layer 55 to cover the second circuit layer 56. Then, a third circuit layer 58 may be formed or disposed on the second dielectric layer 57. At least one second inner via 66 may be formed or disposed in the opening of the second dielectric layer 57, and may contact and electrically connect the second circuit layer 56 and the third circuit layer 58. Then, a third dielectric layer 59 may be formed on the second dielectric layer 57 to cover the third circuit layer 58.

Meanwhile, an upper circuit pattern structure 5 (including the dielectric layers 55, 57, 59 and the circuit layers 54, 56, 58) may be built up on the leveling layer 72. In one embodiment, the leveling layer 72 may be omitted, and the upper circuit pattern structure 5 may be formed or built up on the second surface 402 (e.g., the top surface) of the main body 40 (e.g., the heat dissipating portion). Then, at least one bonding material 85 may be formed or disposed in the opening of the third dielectric layer 59.

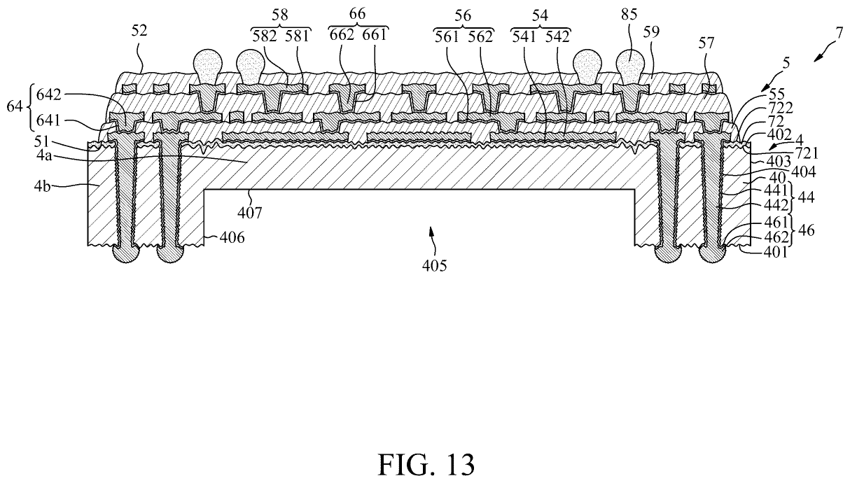

Referring to FIG. 13, a singulation process may be conducted to the main body 40 to obtain an assembly structure 7.

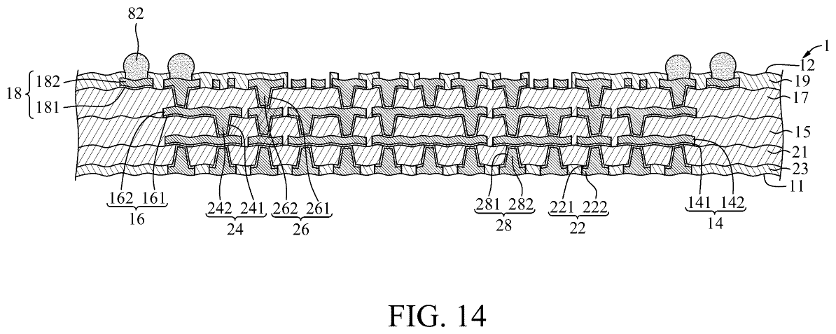

Referring to FIG. 14, a lower circuit pattern structure 1 may be provided. The lower circuit pattern structure 1 of FIG. 14 may be the same as the lower circuit pattern structure 1 of FIG. 1, and may include a plurality of dielectric layers 15, 17, 19, 21, 23, a plurality of circuit layers 14, 16, 18, 22 and a plurality of inner vias 24, 26, 28. At least one bonding material 82 may be formed or disposed in the opening of the third dielectric layer 19.

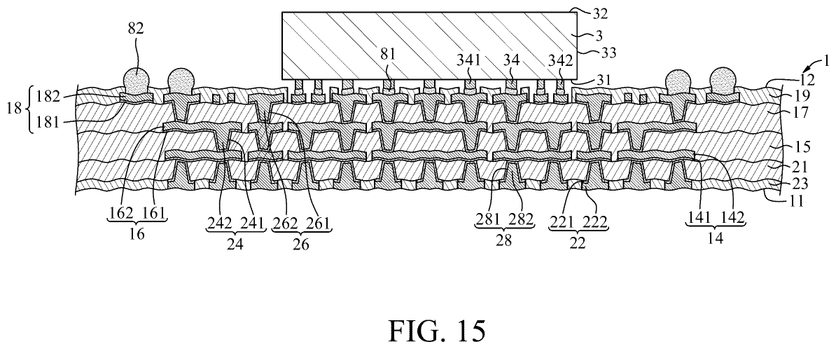

Referring to FIG. 15, an electronic device 3 may be disposed over and electrically connected to the second surface 12 (e.g., the top surface) of the lower circuit pattern structure 1. The electronic device 3 of FIG. 15 may be the same as the electronic device 3 of FIG. 1. The bumps 34 of the electronic device 3 may be bonded to the exposed portions (e.g., exposed pads) of the third circuit layer 18 of the lower circuit pattern structure 1 through a plurality of bonding materials 81.

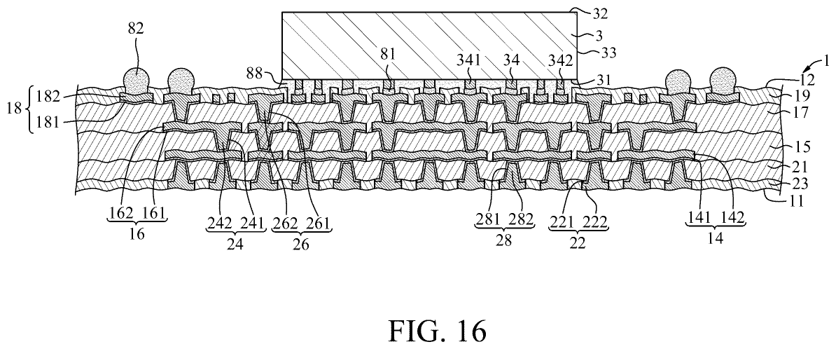

Referring to FIG. 16, an underfill 88 may be formed or disposed between the first surface 31 of the electronic device 3 and the second surface 12 (e.g., the top surface) of the lower circuit pattern structure 1 so as to cover and protect the joint formed by the bumps 34, the bonding materials 81 and the exposed portions (e.g., exposed pads) of the third circuit layer 18 of the lower circuit pattern structure 1.

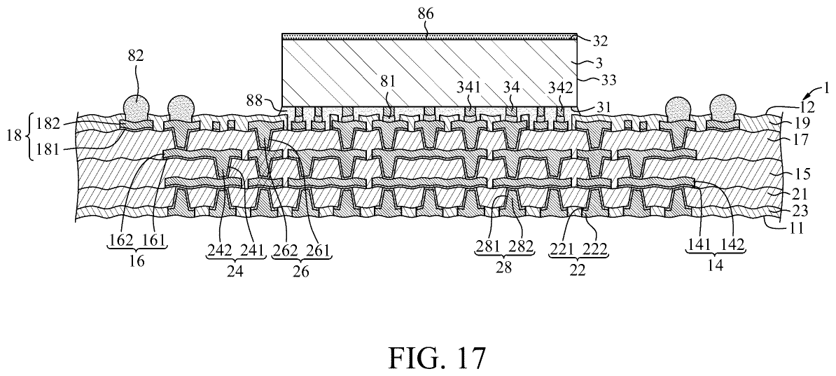

Referring to FIG. 17, a thermal material 86 (e.g., a bonding material or a thermal interface material (TIM)) may be formed or disposed on the second surface 32 (e.g., the top surface) of the electronic device 3.

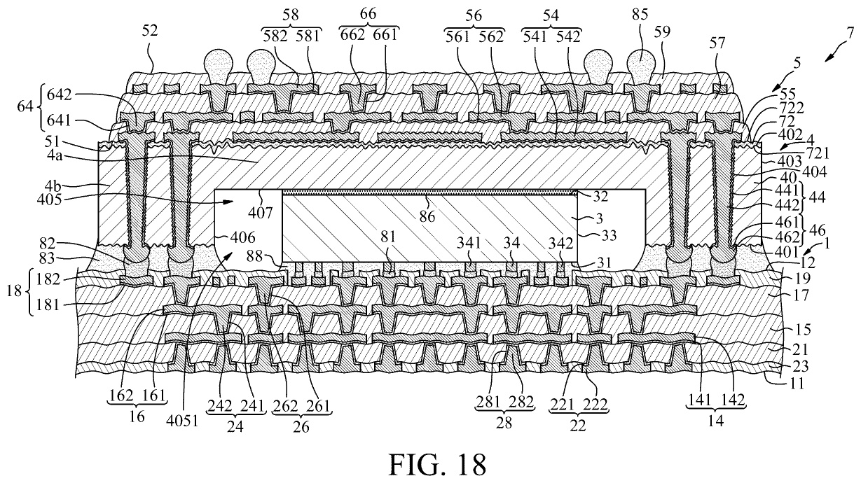

Referring to FIG. 18, the assembly structure 7 of FIG. 13 may be bonded to the lower circuit pattern structure 1, and may cover the electronic device 3. The electronic device 3 may be accommodated in the cavity 405 of the main body 40 (e.g., the heat dissipating portion). The thermal material 86 may contact the top wall 407 of the cavity 405. In some embodiments, the electrical contact 46 of the heat dissipating structure 4 may be bonded to the bonding material 82. Then, an underfill 83 may be formed or disposed between the first surface 401 of the main body 40 and the second surface 12 (e.g., the top surface) of the lower circuit pattern structure 1 so as to cover and protect the joint formed by the electrical contact 46 and the bonding material 82.

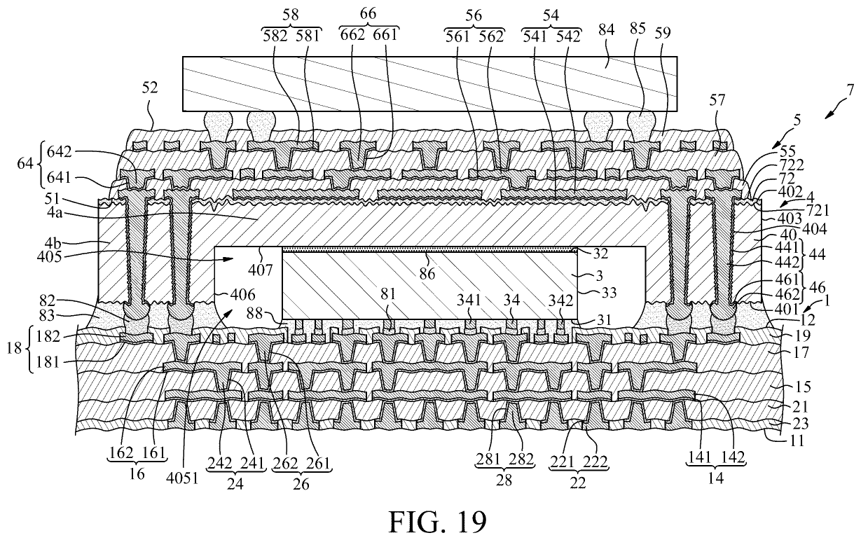

Referring to FIG. 19, an electrical component 84 may be disposed over and electrically connected to the second surface 52 (e.g., the top surface) of the upper circuit pattern structure 5 through the bonding material 85.

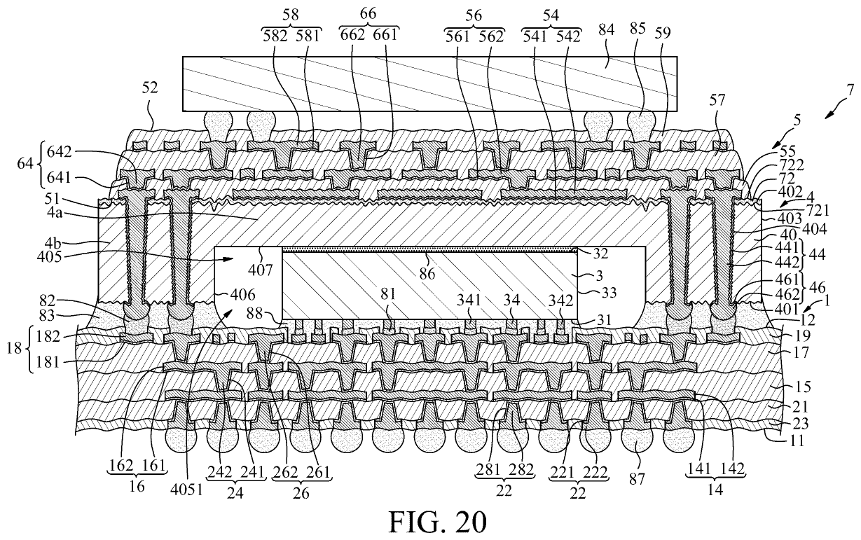

Referring to FIG. 20, a plurality of external connectors 87 may be formed or disposed on the first surface 11 (e.g., the bottom surface) of the lower circuit pattern structure 1. The external connectors 87 may be disposed on the fourth circuit layer 22 of the lower circuit pattern structure 1.

Then, a singulation process may be conducted to the lower circuit pattern structure 1 to obtain a plurality of package structure 8 of FIG. 1.

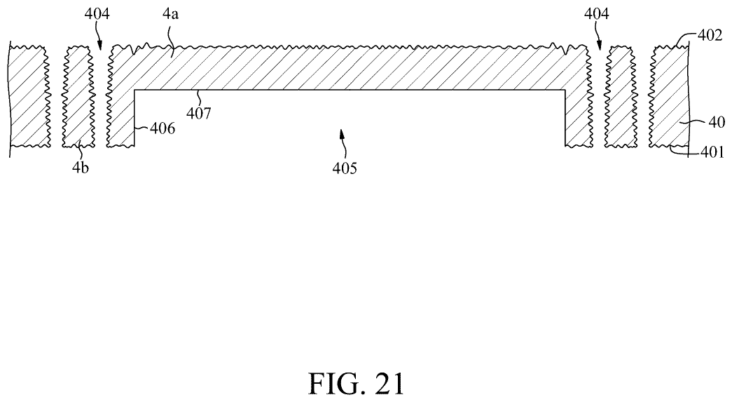

FIG. 21 through FIG. 26 illustrate a method for manufacturing a package structure according to some embodiments of the present disclosure. In some embodiments, the method is for manufacturing the package structure 8a shown in FIG. 3. FIG. 21 through FIG. 25 illustrate a method for manufacturing an assembly structure according to some embodiments of the present disclosure. In some embodiments, the method is for manufacturing the assembly structure 7a shown in FIG. 3.

The initial several stages of the method corresponding to FIG. 21 through FIG. 26 are the same as, or at least similar to, the stages illustrated in FIG. 5 through FIG. 6. FIG. 21 depicts a stage subsequent to that depicted in FIG. 6.

Referring to FIG. 21, at least one through hole 404 may be formed to extend through the second portion 4b of the main body 40 (e.g., the heat dissipating portion). In some embodiments, the through hole 404 may taper from the second surface 402 (e.g., the top surface) of the main body 40 (e.g., the heat dissipating portion) to the first surface 401 (e.g., the bottom surface) of the main body 40 (e.g., the heat dissipating portion).

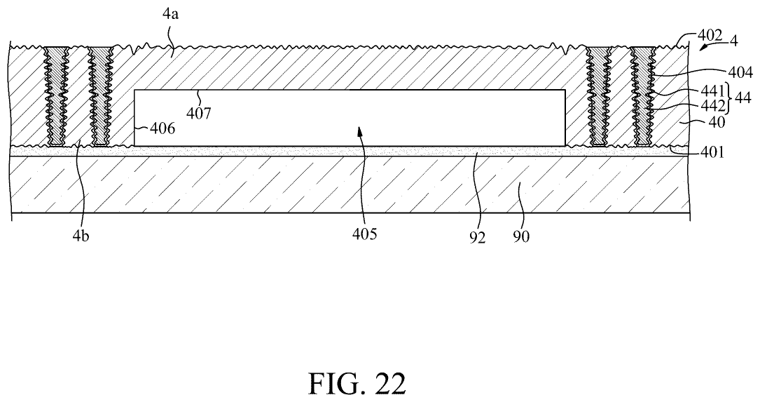

Referring to FIG. 22, the main body 40 (e.g., the heat dissipating portion) may be attached to a release layer 92 on a carrier 90. Then, at least one electrical through via 44 (including the seed layer 441 and the conductive metal material 442) may be formed or disposed in the through hole 404. In some embodiments, a top surface and a bottom surface of the electrical through via 44 may be flat surfaces. That is, a surface roughness Ra, Rz, Ry of the top surface of the electrical through via 44 may be less than a surface roughness Ra, Rz, Ry of the second surface 402 (e.g., the top surface) of the main body 40. A surface roughness Ra, Rz, Ry of the bottom surface of the electrical through via 44 may be less than a surface roughness Ra, Rz, Ry of the first surface 401 (e.g., the bottom surface) of the main body 40. Meanwhile, a heat dissipating structure 4 may be formed on the carrier 90.

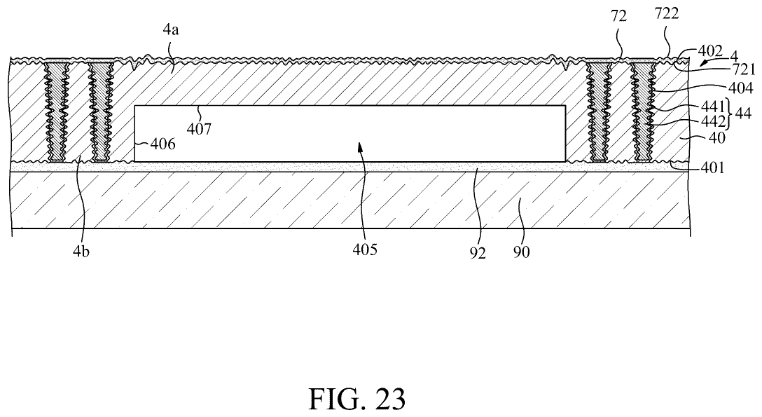

Referring to FIG. 23, a leveling layer 72 may be formed or disposed on the second surface 402 (e.g., the top surface) of the main body 40 (e.g., the heat dissipating portion), and may cover the top surface of the electrical through via 44. Portions of the first surface 721 (e.g., a bottom surface) and the second surface 722 (e.g., a top surface) of the leveling layer 72 corresponding to the top surface of the electrical through via 44 may be flat. That is, a surface roughness Ra, Rz, Ry of a first portion of the second surface 722 (e.g., a top surface) of the leveling layer 72 directly over the top surface of the electrical through via 44 is less than a surface roughness Ra, Rz, Ry of a second portion of the second surface 722 (e.g., a top surface) of the leveling layer 72 other than the first portion.

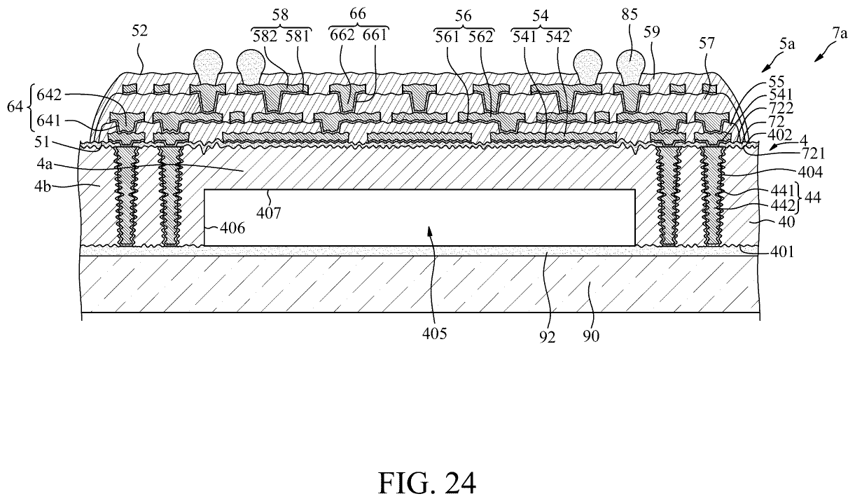

Referring to FIG. 24, an upper circuit pattern structure 5a, which may be the same as the upper circuit pattern structure 5a of FIG. 3, may be built up on the leveling layer 72. In one embodiment, the leveling layer 72 may be omitted, and the upper circuit pattern structure 5a may be formed or built up on the second surface 402 (e.g., the top surface) of the main body 40 (e.g., the heat dissipating portion). Meanwhile, an assembly structure 7a may be formed on the carrier 90. The assembly structure 7a may include the heat dissipating structure 4 and the upper circuit pattern structure 5a.

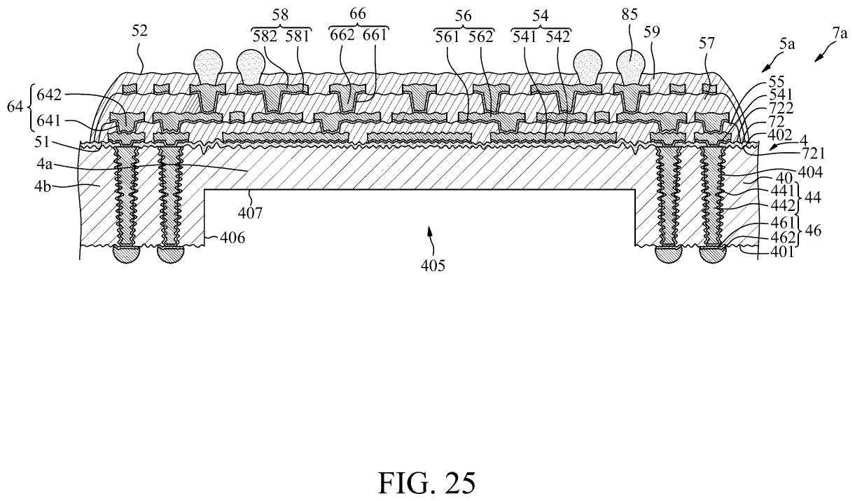

Referring to FIG. 25, the release layer 92 and the carrier 90 may be removed. Then, at least one electrical contact 46 may be formed or disposed on the bottom surface of the electrical through via 44.

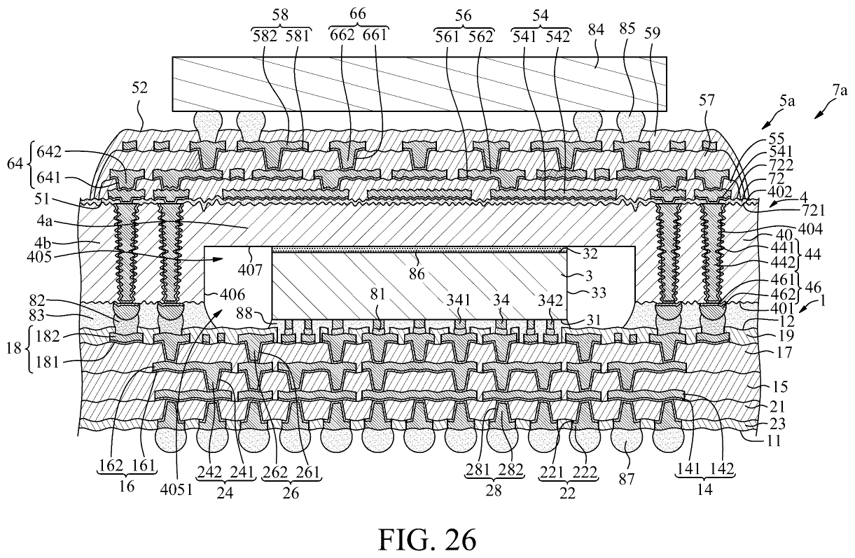

Referring to FIG. 26, the following several stages are the same as, or at least similar to, the stages illustrated in FIG. 14 through FIG. 20. Thus, the assembly structure 7a may be bonded to the lower circuit pattern structure 1, and may cover the electronic device 3.

Then, a singulation process may be conducted to the main body 40 (e.g., the heat dissipating portion) and the lower circuit pattern structure 1 to obtain a plurality of package structure 8a of FIG. 3.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A heat dissipating structure, comprising:
a porous structured main body having a first surface and a second surface opposite to the first surface; and
an electrical through via embedded in the porous structured main body, and extending from the second surface of the porous structured main body to the first surface of the porous structured main body, wherein a hardness of the porous structured main body is greater than a hardness of the electrical through via.

2. The heat dissipating structure of claim 1, wherein a thermal conductivity of the porous structured main body is greater than 1.2 W/mK.

3. The heat dissipating structure of claim 1, wherein the porous structured main body includes ceramic or glass, and the electrical through via includes a conductive material.

4. The heat dissipating structure of claim 1, wherein the porous structured main body includes a sidewall defining a cavity configured for accommodating an electronic device, and the electrical through via is disposed in the sidewall.

5. The heat dissipating structure of claim 4, wherein the cavity is recessed from the first surface of the porous structured main body, and the electrical through via tapers along a direction from the second surface of the porous structured main body to the first surface of the porous structured main body.

6. A package structure, comprising:
a substrate;
an electronic device disposed over the substrate; and
a heat dissipating structure disposed over the substrate and attached to the electronic device, wherein the heat dissipating structure comprises:
a heat dissipating portion configured to guide a heat generated by the electronic device to an outside of the package structure; and
a conductive portion electrically connected to the substrate, and extending through the heat dissipating portion.

7. The package structure of claim 6, wherein the heat dissipating structure further comprises a circuit layer disposed on the heat dissipating portion, and electrically connected to the substrate through the conductive portion.

8. The package structure of claim 7, wherein the heat dissipating portion is configured to guide the heat generated by the electronic device along a thermal path extending in a direction parallel with the top surface of the substrate to the outside of the package structure.

9. The package structure of claim 8, wherein the thermal path extends through the conductive portion.

10. The package structure of claim 7, wherein the conductive portion includes an electrical through via overlapping the electronic device in a direction parallel with a top surface of the substrate.

11. The package structure of claim 10, further comprising a second electronic device disposed over the circuit layer.

12. The package structure of claim 10, further comprising a second inner via connecting to the second circuit layer, wherein a tapering direction of the electrical through via is the same as a tapering direction of the second inner via.

13. The package structure of claim 6, wherein the heat dissipating portion has a first surface, a second surface opposite to the first surface and an outer lateral surface extending between the first surface and the second surface, wherein a surface roughness of the second surface of the heat dissipating portion is greater than a surface roughness of the outer lateral surface of the heat dissipating portion.

14. The package structure of claim 6, further comprising a circuit pattern structure disposed on a top surface of the heat dissipating portion of the heat dissipating structure, wherein a bottom surface of the circuit pattern structure is substantially conformal with the top surface of the heat dissipating portion.

15. The package structure of claim 14, further comprising a leveling layer disposed between the top surface of the heat dissipating portion and the circuit pattern structure, and configured to compensate for a roughness of the top surface of the heat dissipating portion.

16. A package structure, comprising:
a circuit pattern structure;
an electronic device disposed over the circuit pattern structure;
a reinforcement structure spaced apart from the circuit pattern structure and accommodating the electronic device, wherein the reinforcement structure comprises a main body and an electrical through via embedded in the main body; and
a conductive bonding element bonding the reinforcement structure and the circuit pattern structure, wherein the main body of the reinforcement structure is configured to reduce a warpage of the circuit pattern structure during a thermal process.

17. The package structure of claim 16, wherein a coefficient of thermal expansion (CTE) of the main body of the reinforcement structure is less than a CTE of the circuit pattern structure, and the CTE of the main body of the reinforcement structure is less than a CTE of the electrical through via of the reinforcement structure.

18. The package structure of claim 17, wherein a rigidity of the main body of the reinforcement structure is greater than a rigidity of the circuit pattern structure.

19. The package structure of claim 16, wherein the conductive bonding element includes a solder material, wherein the electrical through via is electrically connected to the circuit pattern structure through the solder material.

20. The package structure of claim 16, further comprising a second electronic device disposed over the reinforcement structure, and electrically connected to the circuit pattern structure through the electrical through via.
